(19) United States
(12) Patent Application Publication
(10) Pub. No.: US 2025/0142952 A1
(43) Pub. Date: May 1, 2025

(54) INTEGRATED CIRCUIT DEVICE AND METHOD OF MANUFACTURING THE SAME

(71) Applicant: SAMSUNG ELECTRONICS CO., LTD., Suwon-si (KR)

(72) Inventors: Haegeon JUNG, Suwon-si (KR); Dongkwon Kim, Suwon-si (KR); Myeongji Kim, Suwon-si (KR); Sangduk Park, Suwon-si (KR); Keunhee Bai, Suwon-si (KR); Gahyun Lim, Suwon-si (KR)

(73) Assignee: SAMSUNG ELECTRONICS CO., LTD., Suwon-si (KR)

(21) Appl. No.: 18/796,895

(22) Filed: Aug. 7, 2024

(30) Foreign Application Priority Data
Oct. 25, 2023 (KR) 10-2023-0144179

(51) Int. Cl. H01L 27/092; H01L 21/8238; H01L 23/528; H01L 25/18; H01L 29/06; H01L 29/08; H01L 29/423; H01L 29/66; H01L 29/775; H01L 29/786

(52) U.S. Cl. CPC H10D 84/85; H01L 23/5286; H01L 25/18; H10D 30/014; H10D 30/43; H10D 30/6735; H10D 30/6757; H10D 62/121; H10D 62/151; H10D 64/017; H10D 84/0167; H10D 84/0186; H10D 84/0188; H10D 84/038

(57) ABSTRACT

A method of manufacturing an integrated circuit device is provided. The method includes: providing a substrate including a base substrate layer, an insulating substrate layer, and a cover substrate layer that are sequentially stacked in a vertical direction; forming, on the substrate, a stacked structure including a plurality of sacrificial semiconductor layers and a plurality of nanosheet semiconductor layers that are alternately stacked one layer at a time; and forming a plurality of trench regions to define a plurality of fin-type active regions by etching the stacked structure and the substrate. The he forming of the plurality of trench regions includes, by using the insulating substrate layer as an etch stop layer, etching portions of the stacked structure and the cover substrate layer in the vertical direction up to an upper surface of the insulating substrate layer.

### CROSS-REFERENCE TO RELATED APPLICATION

This application claims priority to Korean Patent Application No. 10-2023-0144179, filed on Oct. 25, 2023, in the Korean Intellectual Property Office, the disclosure of which is incorporated by reference herein in its entirety.

### BACKGROUND

The present disclosure relates to an integrated circuit device and a method of manufacturing the same, and in particular, relates to an integrated circuit device including a back-side power delivery network (BSPDN) structure in which a wiring structure is formed on a backside of a substrate, and a method of manufacturing the same.

As down-scaling of integrated circuit devices progresses, there is a need to secure both high operation speed and operation accuracy in integrated circuit devices. Accordingly, various research is being conducted to provide an integrated circuit device having a structure that may provide optimal performance and improve reliability.

### SUMMARY

One or more embodiments provide a method of manufacturing an integrated circuit device, capable of securing different electrical characteristics according to the types and structures of different devices formed on a same substrate even when the area of a device region is reduced due to down-scaling of the integrated circuit device, and capable of providing a structure that is easy to form a back-side power delivery network (BSPDN) structure.

According to an aspect of an embodiment, a method of manufacturing an integrated circuit device includes: providing a substrate including a base substrate layer, an insulating substrate layer, and a cover substrate layer that are sequentially stacked in a vertical direction; forming, on the substrate, a stacked structure including a plurality of sacrificial semiconductor layers and a plurality of nanosheet semiconductor layers that are alternately stacked one layer at a time; and forming a plurality of trench regions to define a plurality of fin-type active regions by etching the stacked structure and the substrate. The forming of the plurality of trench regions includes, by using the insulating substrate layer as an etch stop layer, etching portions of the stacked structure and the cover substrate layer in the vertical direction up to an upper surface of the insulating substrate layer.

In addition, according to another aspect of an embodiment, an integrated circuit device includes: a substrate including a base substrate layer and an insulating substrate layer; a plurality of fin-type active regions protruding from a frontside surface of the substrate in a vertical direction and extending long in a first horizontal direction to define a trench region on the substrate; a plurality of source/drain regions on the plurality of fin-type active regions; a device isolation layer on a sidewall of each of the plurality of fin-type active regions in the trench region; a via power rail between the plurality of fin-type active regions, between the plurality of source/drain regions and penetrating the device isolation layer in the vertical direction; and a backside power rail penetrating the substrate in the vertical direction from a backside surface of the substrate to contact an end of the via power rail. A lower surface of the trench region and an upper surface of the insulating substrate layer are provided at a same vertical level.

In addition, according to another aspect of an embodiment, an integrated circuit device includes: a substrate including a base substrate layer including a semiconductor material and an insulating substrate layer, the insulating substrate layer including silicon oxide (SiOx), silicon nitride (SIN), or a combination thereof; a plurality of cell regions spaced apart from each other on the substrate in a first horizontal direction and each including a plurality of cells; an inter-cell separation region on the substrate between the plurality of cell regions, and extending long in a second horizontal direction crossing the first horizontal direction; a plurality of power lines on a backside surface of the substrate, the plurality of power lines crossing the plurality of cell regions and the inter-cell separation region, and extending in parallel in the first horizontal direction; a plurality of via power rails in the inter-cell separation region; and a backside power rail penetrating the substrate in a vertical direction from the backside surface of the substrate to contact an end of each of the plurality of via power rails. Each of the plurality of cells includes: a fin-type active region protruding from a frontside surface of the substrate in the vertical direction and extending long in the first horizontal direction to define a trench region on the substrate; a device isolation layer on sidewalls of the fin-type active region in the trench region; at least one nanosheet provided on the fin-type active region; and a gate line surrounding the at least one nanosheet and extending long in the second horizontal direction. A lower surface of the trench region and a vertical level of an upper surface of the insulating substrate layer are provided at a same vertical level.

### BRIEF DESCRIPTION OF DRAWINGS

The above and other aspects will be more apparent from the following description of embodiments taken in conjunction with the accompanying drawings, in which:

FIG. 1 is a block diagram of an integrated circuit device, according to an embodiment;

FIG. 2A is a plan view of a main configuration of some regions that may be included in a memory region of the integrated circuit device shown in FIG. 1;

FIG. 2B is a cross-sectional view taken along a line X1-X1′ of FIG. 2A;

FIG. 2C is a cross-sectional view taken along a line Y1-Y1′ of FIG. 2A;

FIG. 3A is a planar layout diagram of a logic region of an integrated circuit device, according to an embodiment;

FIG. 3B is a planar layout diagram for explaining an example configuration of any one of a plurality of cells shown in FIG. 3A;

FIGS. 4A to 4C are drawings for explaining example configurations of some regions of the plurality of cells and an inter-cell separation region, shown in FIG. 3A, wherein FIG. 4A is an enlarged partial cross-sectional view taken along a line X31-X31′ of FIG. 3A, FIG. 4B is an enlarged partial cross-sectional view taken along a line X32-X32′ of FIG. 3A, and FIG. 4C is an enlarged partial cross-sectional view taken along a line Y3-Y3′ of FIGS. 3A and 3B;

FIG. 5A is a plan view of a plurality of fin-type active regions defined by a trench region in a memory region of an integrated circuit device, according to an embodiment;

FIG. 5B is a plan view of a plurality of fin-type active regions defined by a trench region in a logic region of an integrated circuit device, according to an embodiment; and

FIGS. 6 to 16B are shown according to a process sequence to explain an example method of manufacturing an integrated circuit device, according to embodiments, wherein, more specifically, FIGS. 9A, 10A, 11A, 12A, 13A, 14A, 15A, and 16A are enlarged cross-sectional views of some configurations according to a process sequence in a portion corresponding to a cross-section taken along a line X31-X31′ of FIG. 3A, and FIGS. 6, 7, 8, 9B, 10B, 11B, 12B, 13B, 14B, 15B, and 16B are enlarged cross-sectional views of some configurations according to a process sequence in a portion corresponding to a cross-section taken along a line X32-X32′ of FIG. 3A.

### DETAILED DESCRIPTION

Embodiments will now be described more fully with reference to the accompanying drawings. Like reference numerals in the accompanying drawings refer to like elements throughout, and duplicate descriptions thereof are omitted. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

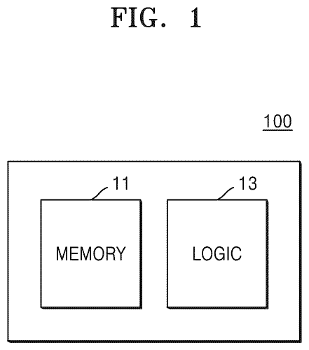

FIG. 1 is a block diagram of an integrated circuit device that may be implemented according to method of manufacturing an integrated circuit device, according to an embodiment.

Referring to FIG. 1, an integrated circuit device 100 may include a memory region 11 and a logic region 13. The memory region 11 may include at least one of static random-access memory (SRAM), dynamic random access memory (DRAM), magnetoresistive random-access memory (MRAM), resistive random-access memory (RRAM), and phase-change memory (PRAM). The logic region 13 may include standard cells that perform desired logical functions, such as a counter, a buffer, etc. The standard cells may include various types of logic cells including a plurality of circuit elements such as a transistor, a resistor, etc. The logic cells may constitute, for example, AND, NAND, OR, NOR, exclusive OR (XOR), exclusive NOR (NOR), inverter (INV), adder (ADD), buffer (BUF), delay (DLY), filter (FIL), a multiplexer (MXT/MXIT), OR/AND/INVERTER (OAI), AND/OR (AO), AND/OR/INVERTER (AOI), D flip-flop, reset flip-flop, master-slave flip-flop, latch, etc.

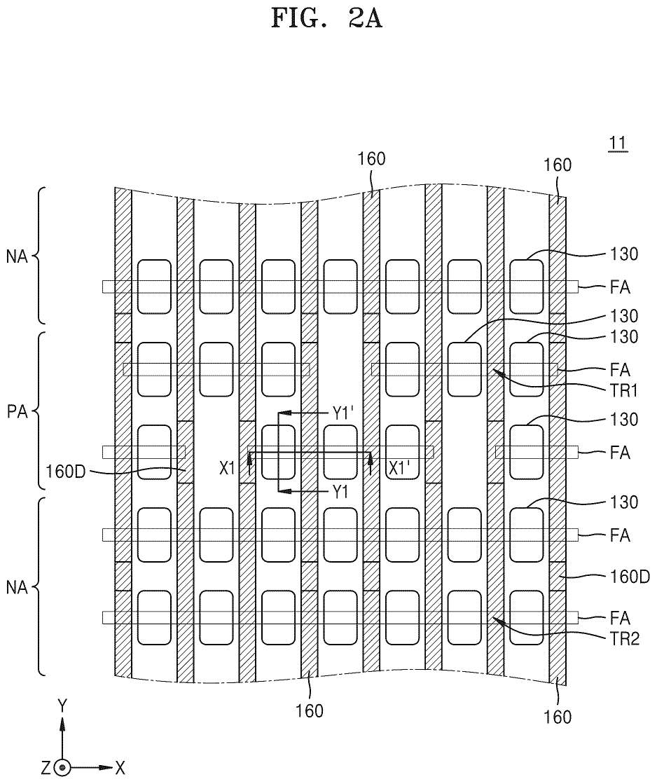

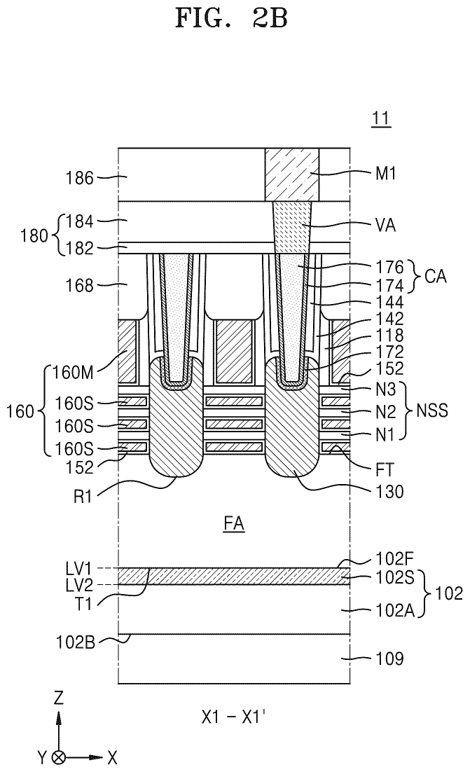

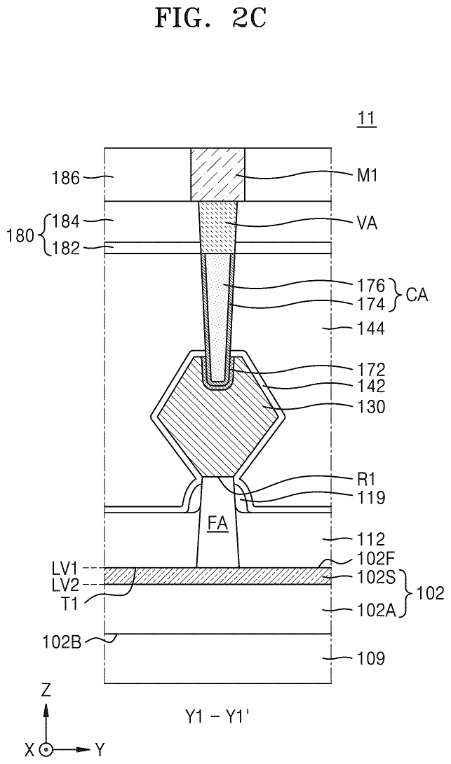

FIG. 2A is a plan view of main components of some regions that may be included in a memory region of the integrated circuit device shown in FIG. 1.

FIG. 2B is a cross-sectional view taken along a line X1-X1′ of FIG. 2A.

FIG. 2C is a cross-sectional view taken along a line Y1-Y1′ of FIG. 2A.

Referring to FIGS. 1 and 2A to 2C, the integrated circuit device 100 includes, in the memory region 11, field-effect transistors having a gate-all-around structure including a nanowire or nanosheet-shaped active region and a gate surrounding the active region.

Referring to FIGS. 2A to 2C, the memory region 11 of the integrated circuit device 100 may include a plurality of fin-type active regions FA that protrude upward from a substrate 102 in a vertical direction (Z direction) and extend long in a first horizontal direction (X direction) in a plurality of n-type metal-oxide-semiconductor field-effect transistors (NMOS) transistor regions NA and a plurality of p-type metal-oxide-semiconductor field-effect transistors (PMOS) transistor regions PA. A plurality of nanosheet stacks NSS may be disposed over the plurality of fin-type active regions FA. Each of the plurality of nanosheet stacks NSS may include at least one nanosheet facing a fin upper surface FT at a position spaced apart from the fin upper surface FT of a fin-type active region FA in the vertical direction (Z direction). The term “nanosheet” used herein may refer to a conductive structure having a cross-section substantially perpendicular to a direction in which current flows. The nanosheet should be understood to include a nanowire.

The substrate 102 may include a base substrate layer 102A and an insulating substrate layer 102S. The base substrate layer 102A and the insulating substrate layer 102S may be sequentially stacked.

The base substrate layer 102A may include a semiconductor material such as Si or Ge, or a compound semiconductor material such as SiGe, SiC, GaAs, InAs, or InP. In some embodiments, the base substrate layer 102A may include at least one of a Group III-V material and a Group IV material.

The insulating substrate layer 102S may include an insulating material. The insulating substrate layer 102S may include, for example, silicon oxide (SiOx), silicon nitride (SIN), or a combination thereof. However, embodiments are not limited thereto, and the insulating substrate layer 102S may include one insulating layer of silicon oxynitride (SiON), germanium oxide (GeOx), germanium nitride (GeNx), aluminum oxide (Al₂O₃), tantalum oxide (Ta₂O₅), hafnium oxide (HfO₂), and aluminum nitride (AIN), or a structure of a stack of at least two insulating layers thereof. The insulating substrate layer 102S may have a thickness of several tens of nm. For example, the insulating substrate layer 102S may have a thickness of about 10 nm to about 20 nm. In this state, an upper surface of the insulating substrate layer 102S may be the same as a frontside surface 102F of the substrate 102.

A device isolation layer 112 (see FIG. 2C) which covers both sidewalls of each of the plurality of fin-type active regions FA may be disposed on the substrate 102. The device isolation layer 112 may include an oxide layer, a nitride layer, or a combination thereof.

A plurality of gate lines 160 may be disposed over the plurality of fin-type active regions FA. Each of the plurality of gate lines 160 may extend long in a second horizontal direction (Y direction) perpendicular to the first horizontal direction (X direction). Each of the plurality of nanosheet stacks NSS may be disposed over the fin upper surface FT of the fin-type active region FA in a portion where the plurality of fin-type active regions FA and the plurality of gate lines 160 intersect each other. A local region of each of the plurality of gate lines 160 may constitute a dummy gate 160D. Portions spaced apart from each other with the dummy gate 160D therebetween in each of the plurality of gate lines 160 may be configured to be electrically separable from each other by the dummy gate 160D.

Each of the plurality of nanosheet stacks NSS may include a plurality of nanosheets, for example, a first nanosheet N1, a second nanosheet N2, and a third nanosheet N3, which overlap each other in the vertical direction (Z direction) on the fin-type active region FA. The first nanosheet N1, the second nanosheet N2, and the third nanosheet N3 may be different vertical distances (Z-direction distances) from an upper surface of the fin-type active region FA. The first nanosheet N1, the second nanosheet N2, and the third nanosheet N3, which are included in the nanosheet stack NSS, may each have a channel region.

A plurality of recesses R1 may be formed on the fin-type active region FA in an NMOS transistor region NA and a PMOS transistor region PA. A vertical level of a lowest surface of each of the plurality of recesses R1 may be lower than a vertical level of the fin upper surface FT of the fin-type active region FA. The term “vertical level” used herein may refer to a distance from the frontside surface 102F of the substrate 102 in a vertical direction (Z direction or-Z direction).

A plurality of source/drain regions 130 may be arranged in the plurality of recesses R1. Each of the plurality of source/drain regions 130 may be arranged adjacent to at least one gate line 160 selected from among the plurality of gate lines 160. Each of the plurality of source/drain regions 130 may be in contact with the first nanosheet N1, the second nanosheet N2, and the third nanosheet N3, which are included in the nanosheet stack NSS adjacent thereto.

In the PMOS transistor region PA, a PMOS transistor TR1 may be formed in each of portions in which the plurality of fin-type active regions FA and the plurality of gate lines 160 intersect each other, and in the NMOS transistor region NA, an NMOS transistor TR2 may be formed in each of portions in which the plurality of fin-type active regions FA and the plurality of gate lines 160 intersect each other.

Some of the plurality of fin-type active regions FA may be disposed on the substrate 102 at a constant pitch. Some others of the plurality of fin-type active regions FA may be formed at a variable pitch, such that a separation distance between two neighboring fin-type active regions FA may vary depending on their positions.

Each of the plurality of source/drain regions 130 may include an epitaxially grown semiconductor layer. In some embodiments, each of the plurality of source/drain regions 130 may include an embedded SiGe structure including an epitaxially grown Si layer, an epitaxially grown SiC layer, a plurality of epitaxially grown SiGe layers. When a source/drain region 130 constitutes an NMOS transistor, the source/drain region 130 may include a Si layer doped with an n-type dopant or a SiC layer doped with an n-type dopant. The n-type dopant may be selected from phosphorus (P), arsenic (As), and antimony (Sb). When the source/drain region 130 constitutes a PMOS transistor, the source/drain region 130 may include a SiGe layer doped with a p-type dopant. The p-type dopant may be selected from boron (B) and gallium (Ga).

Each of the plurality of gate lines 160 may include a main gate portion 160M and a plurality of sub-gate portions 160S. The main gate portion 160M may extend in the second horizontal direction (Y direction) while covering an upper surface of the nanosheet stack NSS. The plurality of sub-gate portions 160S may be integrally connected to the main gate portion 160M, and may respectively be arranged between the first nanosheet N1 and the second nanosheet N2, between the second nanosheet N2 and the third nanosheet N3, and between the first nanosheet N1 and the fin-type active region FA. Each of the plurality of gate lines 160 may include metal, metal nitride, metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may be TiAlC.

A gate dielectric layer 152 may be arranged between the nanosheet stack NSS and a gate line 160. The gate dielectric layer 152 may include a structure of a stack of an interface dielectric layer and a high dielectric layer. The interface dielectric layer may include a low dielectric material layer having a dielectric constant of about 9 or less, for example, a silicon oxide layer, a silicon oxynitride layer, or a combination thereof. In some embodiments, the interface dielectric layer may be omitted. The high dielectric layer may include a material having a higher dielectric constant than a silicon oxide layer. For example, the high dielectric layer may have a dielectric constant of about 10 to about 25. The high dielectric layer may include hafnium oxide, but is not limited thereto.

A plurality of outer insulating spacers 118 which cover both sidewalls of the gate line 160 may be disposed on the fin-type active region FA and the device isolation layer 112. Each of the plurality of outer insulating spacers 118 may be spaced apart from the gate line 160 with the gate dielectric layer 152 therebetween. An upper surface of each of the gate dielectric layer 152, the gate line 160 and an outer insulating spacer 118 may be covered by a capping insulating pattern 168. The capping insulating pattern 168 may include a silicon nitride layer.

As shown in FIG. 2C, both sidewalls of a lower portion of the fin-type active region FA between the device isolation layer 112 and the source/drain region 130 may be covered by a recess-side insulating spacer 119. In some embodiments, the recess-side insulating spacer 119 may be integrally connected to the outer insulating spacer 118 adjacent thereto. Each of the outer insulating spacer 118 and the recess-side insulating spacer 119 may include silicon nitride (SiN), silicon oxide (SiO), SiCN, SiBN, SiON, SiOCN, SiBCN, SiOC, or a combination thereof.

The source/drain region 130, the outer insulating spacer 118, and the recess-side insulating spacer 119 may each be covered by an insulating liner 142. The insulating liner 142 may include silicon nitride (SiN), silicon oxide (SiO), SiCN, SiBN, SiON, SiOCN, SiBCN, SiOC, or a combination thereof. An inter-gate insulating layer 144 may be disposed on the insulating liner 142. The inter-gate insulating layer 144 may include a silicon nitride layer, a silicon oxide layer, SiON, SiOCN, or a combination thereof.

A plurality of source/drain contacts CA may be disposed over the plurality of source/drain regions 130. A metal silicide layer 172 may be arranged between the source/drain region 130 and a source/drain contact CA, which are connected to each other. Each of the plurality of source/drain contacts CA may include a conductive barrier layer 174 and a contact plug 176, which are sequentially stacked over the source/drain region 130. The conductive barrier layer 174 may be in contact with a lower surface and sidewall of the contact plug 176 while surrounding a lower surface and sidewall of the contact plug 176. The conductive barrier layer 174 may be arranged between the metal silicide layer 172 and the contact plug 176. In some embodiments, the conductive barrier layer 174 may include metal or metal nitride. For example, the conductive barrier layer 174 may include Ti, Ta, W, TiN, TaN, WN, WCN, TiSIN, TaSiN, WSiN, or a combination thereof, but is not limited thereto. The contact plug 176 may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but is not limited thereto. The metal silicide layer 172 may include a metal including Ti, W, Ru, Nb, Mo, Hf, Ni, Co, Pt, Yb, Tb, Dy, Er, or Pd. For example, the metal silicide layer 172 may include titanium silicide, but is not limited thereto.

An upper surface of each of the plurality of source/drain contacts CA, a plurality of capping insulating patterns 168 and the inter-gate insulating layer 144 may be covered by an upper insulating structure 180. The upper insulating structure 180 may include an etch stop layer 182 and an upper insulating layer 184. The etch stop layer 182 may include silicon carbide (SiC), SiN, nitrogen-doped silicon carbide (SiC:N), SiOC, AlN, AlON, AlO, AlOC, or a combination thereof. The upper insulating layer 184 may include an oxide layer, a nitride layer, an ultra low-k (ULK) layer having an ultra low dielectric constant K of about 2.2 to about 2.4, or a combination thereof. For example, the upper insulating layer 184 may include tetraethyl orthosilicate (TEOS) layer, a high-density plasma (HDP) oxide layer, a boro-phospho-silicate glass (BPSG) layer, a flowable chemical vapor deposition (FCVD) oxide layer, a SiON layer, a SiN layer, a SiOC layer, a SiCOH layer, or a combination thereof, but is not limited thereto.

A plurality of source/drain via contacts VA may be disposed on the plurality of source/drain contacts CA. Some of the plurality of source/drain via contacts VA may be in contact with the source/drain contact CA through the upper insulating structure 180.

An interlayer insulating layer 186 may be disposed on the upper insulating structure 180 and the plurality of source/drain via contacts VA. Some of a plurality of upper wiring layers M1 may be connected to a source/drain via contact VA through the interlayer insulating layer 186. A material of the interlayer insulating layer 186 is substantially the same as described in connection with a material of the upper insulating layer 184. Each of the plurality of upper wiring layers MI may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but is not limited thereto.

As shown in FIGS. 2B and 2C, a backside surface 102B of the substrate 102 may be covered by a backside insulating layer 109. The backside insulating layer 109 may include a silicon oxide layer, a silicon nitride layer, a silicon carbide layer, a low dielectric layer, or a combination thereof. The low dielectric layer may include fluorine-doped silicon oxide, organosilicate glass, carbon-doped oxide, porous silicon oxide, porous organosilicate glass, spin-on organic polymeric dielectric, spin-on silicon based polymeric dielectric, or a combination thereof, but is not limited thereto.

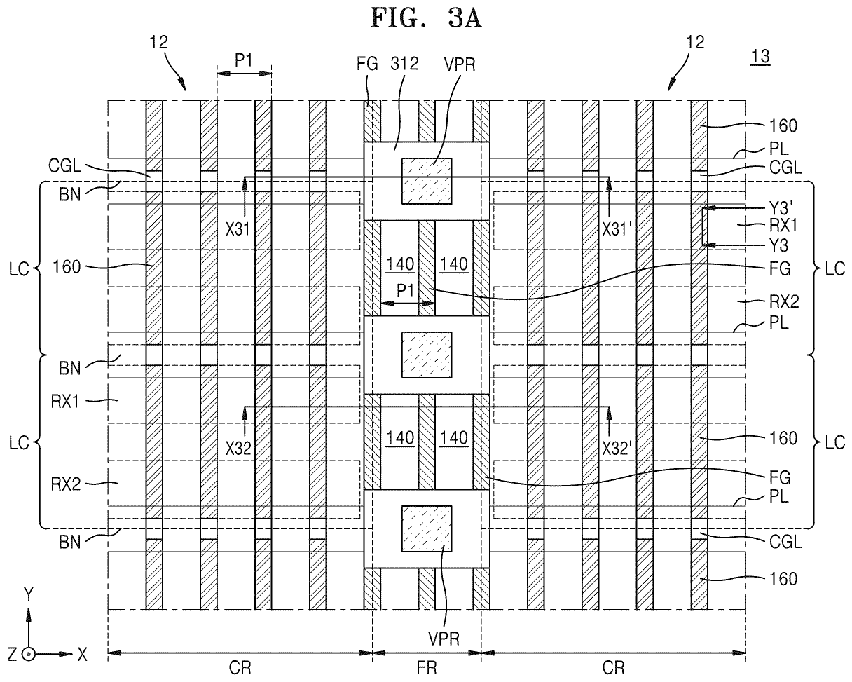

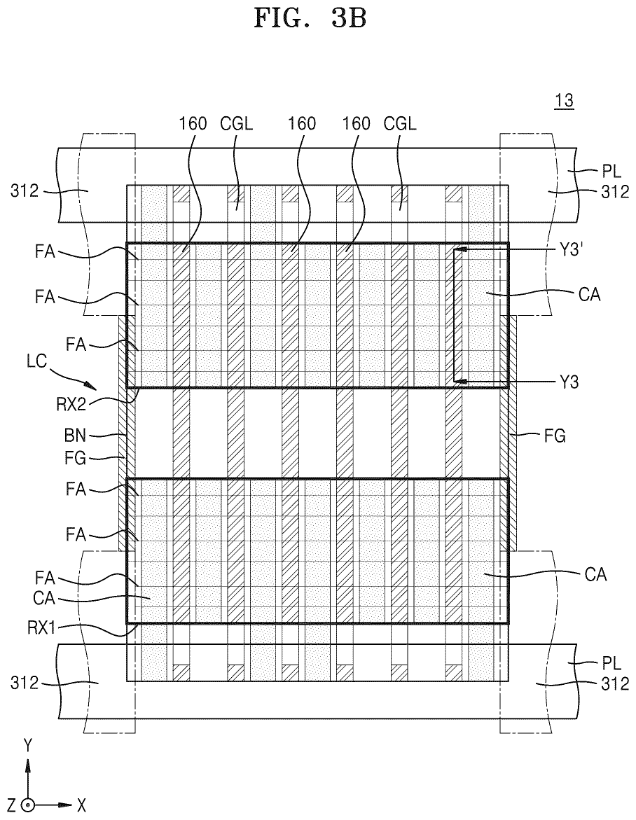

FIG. 3A is a planar layout diagram of a logic region of an integrated circuit device, according to an embodiment.

FIG. 3B is a planar layout diagram for explaining an example configuration of any one of a plurality of cells shown in FIG. 3A.

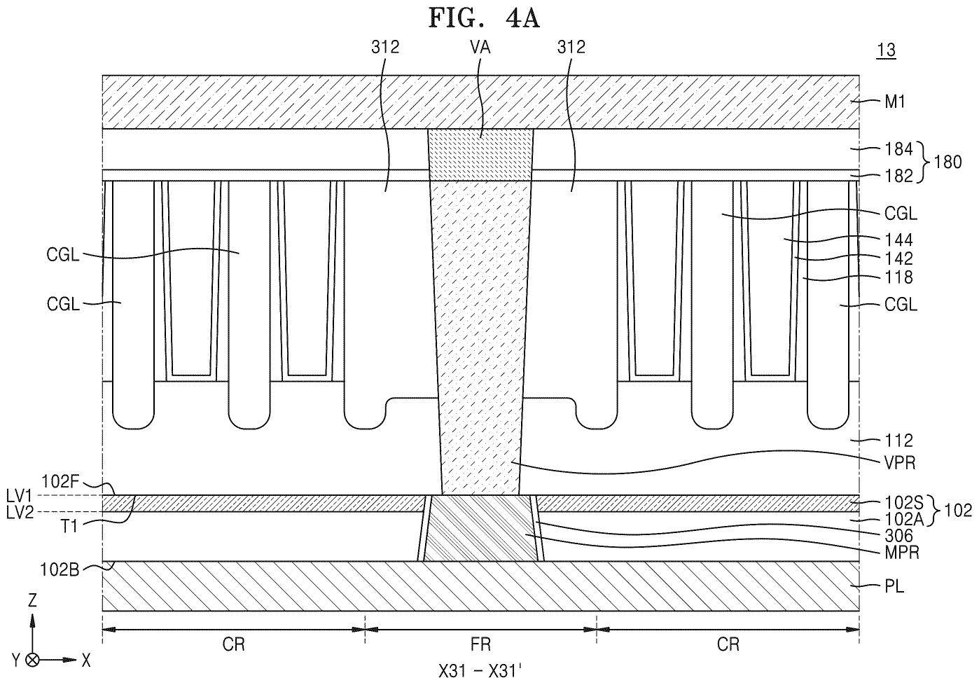

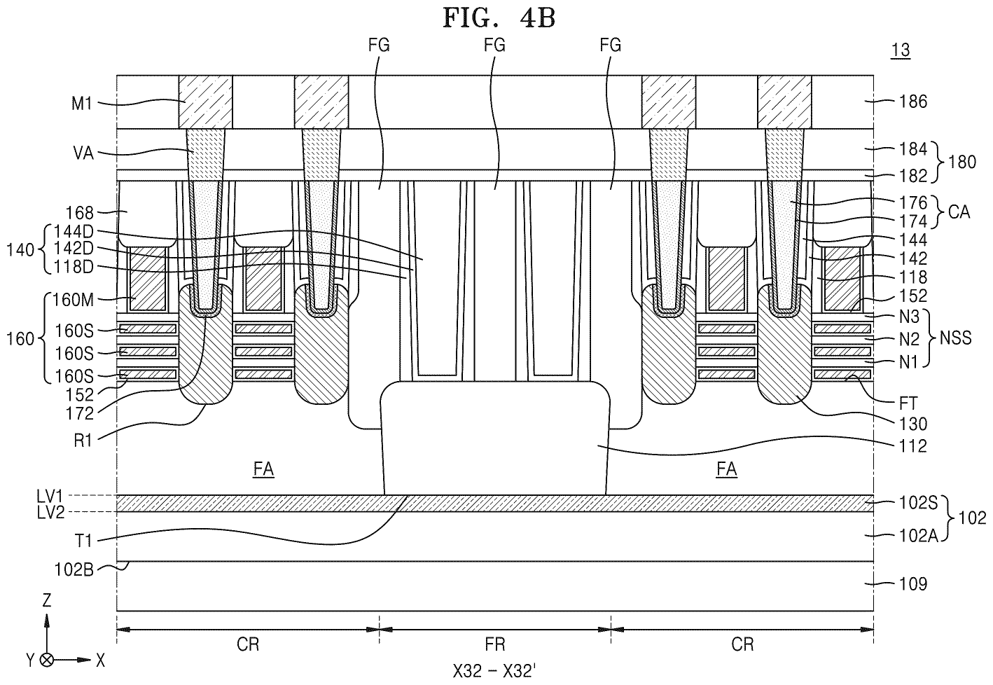

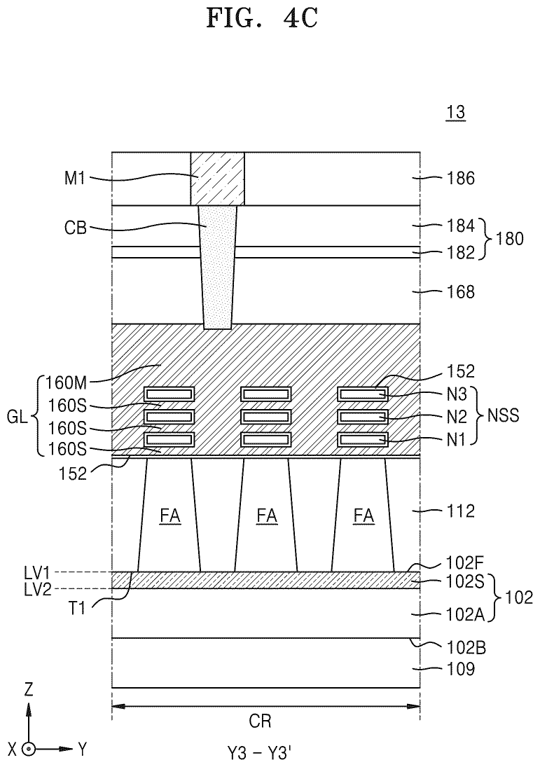

FIGS. 4A to 4C are drawings for explaining example configurations of some regions of the plurality of cells and an inter-cell separation region, shown in FIG. 3A, wherein FIG. 4A is an enlarged partial cross-sectional view taken along a line X31-X31′ of FIG. 3A, FIG. 4B is an enlarged partial cross-sectional view taken along a line X32-X32′ of FIG. 3A, and FIG. 4C is an enlarged partial cross-sectional view taken along a line Y3-Y3′ of FIGS. 3A and 3B.

In FIGS. 3A, 3B, and 4A to 4C, reference numerals that are the same as those in FIGS. 2A to 2C denote members that are the same as those in FIGS. 2A to 2C, and detailed descriptions thereof are not provided.

Referring to FIGS. 3A, 3B, and 4A to 4C, the logic region 13 of the integrated circuit device 100 may include a plurality of cell regions CR spaced apart from each other in the first horizontal direction (X direction). Each of the plurality of cell regions CR may include a plurality of cells LC arranged in a row in the second horizontal direction (Y direction) crossing the first horizontal direction (X direction). An inter-cell separation region FR extending long in the second horizontal direction (Y direction) may be arranged between two cell regions CR that are adjacent to each other in the first horizontal direction (X direction) among the plurality of cell regions CR.

The plurality of gate lines 160 may extend long in the second horizontal direction (Y direction) in each of the plurality of cells LC included in the plurality of cell regions CR. A plurality of dummy gate insulating lines FG may extend long in the second horizontal direction (Y direction) in the inter-cell separation region FR. The plurality of dummy gate insulating lines FG and the plurality of gate lines 160 included in each of the plurality of cells LC may be arranged at a constant pitch P1 in the first horizontal direction (X direction).

A cell region CR may include a cell block 12 including the plurality of cells LC. The cell block 12 may include the plurality of cells LC including circuit patterns for forming various circuits. The plurality of cells LC may be arranged in the form of a matrix in the first horizontal direction (X direction) and the second horizontal direction (Y direction) in the cell block 12.

The integrated circuit device 100 may include a plurality of power lines PL. Each of the plurality of power lines PL may cross the plurality of cell regions CR and the inter-cell separation region FR in the first horizontal direction (X direction) and extend long in the first horizontal direction (X direction). Each of the plurality of power lines PL may be configured to supply power to the plurality of cells LC arranged in one row extending in the first horizontal direction (X direction) in the plurality of cell regions CR.

The plurality of power lines PL may be disposed on the backside surface 102B of the substrate 102. The plurality of power lines PL may include a portion that overlaps a cell boundary BN of each of the plurality of cells LC in the vertical direction (Z direction), but are not limited thereto.

Each of the plurality of cells LC may include a first device region RX1 and a second device region RX2. The plurality of fin-type active regions FA protruding from the frontside surface 102F of the substrate 102 in the vertical direction (Z direction) may be arranged in each of the first device region RX1 and the second device region RX2.

A trench region T1 is defined between each of the plurality of fin-type active regions FA in the first device region RX1 and the second device region RX2, and the trench region T1 may be filled with the device isolation layer 112. In some embodiments, one of the first device region RX1 and the second device region RX2 may be an NMOS transistor region, and the other one may be a PMOS transistor region.

As shown in FIGS. 4A and 4B, the device isolation layer 112 may cover the frontside surface 102F of the substrate 102 in the cell region CR and the inter-cell separation region FR. The device isolation layer 112 may cover an upper surface of the insulating substrate layer 102S in the cell region CR and the inter-cell separation region FR.

As shown in FIG. 4B, a portion of the device isolation layer 112, which is in the inter-cell separation region FR, may cover both sidewalls of each of the plurality of fin-type active regions FA in the first horizontal direction (X direction). In the first device region RX1 and the second device region RX2, the plurality of gate lines 160 may extend long in the second horizontal direction (Y direction) over the plurality of fin-type active regions FA and the device isolation layer 112.

As shown in FIGS. 4B and 4C, in regions where the plurality of fin-type active regions FA and the plurality of gate lines 160 intersect, the plurality of nanosheet stacks NSS may be disposed over the fin upper surface FT of each of the plurality of fin-type active regions FA. The plurality of nanosheet stacks NSS may each include the first nanosheet N1, the second nanosheet N2, and the third nanosheet N3. More detailed configurations of the plurality of fin-type active regions FA, the plurality of gate lines 160, and the plurality of nanosheet stacks NSS are substantially the same as those described with reference to FIGS. 2A to 2C.

In some embodiments, the plurality of source/drain regions 130 in the first device region RX1 and the plurality of source/drain regions 130 in the second device region RX2 may have different shapes and sizes. The shape of each of the plurality of source/drain regions 130 is not limited to that shown in FIG. 4B, and the plurality of source/drain regions 130 having various shapes and various sizes may be formed in the first device region RX1 and the second device region RX2.

The metal silicide layer 172 may be formed on an upper surface of each of the plurality of source/drain regions 130. Over the substrate 102, the plurality of source/drain regions 130, a plurality of metal silicide layers 172, and the plurality of outer insulating spacers 118 may be covered by the insulating liner 142. The inter-gate insulating layer 144 may be disposed on the insulating liner 142. In the plurality of cells LC, the device isolation layer 112, the insulating liner 142, and the inter-gate insulating layer 144 may form a portion of an insulating structure.

As shown in FIGS. 3A and 3B, a plurality of gate cut insulating patterns CGL may be disposed on the cell boundary BN of each of the plurality of cells LC, which extends in the first horizontal direction (X direction). The plurality of gate cut insulating patterns CGL may be respectively disposed on extensions of the plurality of gate lines 160. In some embodiments, the plurality of gate cut insulating patterns CGL may include a silicon nitride layer, but are not limited thereto. FIGS. 3A and 3B show configurations in which the plurality of gate cut insulating patterns CGL extend in the second horizontal direction (Y direction) across the cell boundary BN of each of a pair of cells LC adjacent to each other in the second horizontal direction (Y direction) in the cell block 12, but the position and planar shape of each of the plurality of gate cut insulating patterns CGL are not limited to those shown in FIGS. 3A and 3B.

The plurality of dummy gate insulating lines FG may extend long in the second horizontal direction (Y direction) over the frontside surface 102F of the substrate 102 in the inter-cell separation region FR. The plurality of dummy gate insulating lines FG may be arranged at the constant pitch P1 in the first horizontal direction (X direction) together with the plurality of gate lines 160 included in the plurality of cells LC. Among the plurality of dummy gate insulating lines FG, a plurality of dummy gate insulating lines FG arranged along a straight line in the second horizontal direction (Y direction) may extend intermittently in the second horizontal direction (Y direction). FIG. 3A shows a configuration in which, between a pair of cells LC spaced apart from each other in the first horizontal direction (X direction), three dummy gate insulating lines FG are arranged parallel to each other in the inter-cell separation region FR. However, the number and shape of dummy gate insulating lines FG arranged in the inter-cell separation region FR may vary.

As shown in FIG. 4B, in the inter-cell separation region FR, a dummy insulating structure 140 may be arranged between each of the plurality of dummy gate insulating lines FG. The dummy insulating structure 140 may include a dummy insulating spacer 118D, a dummy insulating liner 142D, and an inter-dummy gate insulating layer 144D. A material of each of the dummy insulating spacer 118D, the dummy insulating liner 142D, and the inter-dummy gate insulating layer 144D is the same as described in connection with each of the outer insulating spacer 118, the insulating liner 142, and the inter-gate insulating layer 144, which are arranged in the cell region CR.

As shown in FIG. 4B, the device isolation layer 112 in the inter-cell separation region FR may include a portion between a plurality of dummy insulating structures 140 and the substrate 102 and between the plurality of dummy gate insulating lines FG and the substrate 102.

As shown in FIGS. 3A and 4A, a plurality of through insulating patterns 312 may be arranged in the inter-cell separation region FR. The plurality of through insulating patterns 312 are spaced apart from each other in the second horizontal direction (Y direction), and may be arranged in a row along a straight line in the second horizontal direction (Y direction). Each of the plurality of through insulating patterns 312 may be arranged at a position overlapping one power line PL in a vertical direction. As shown in FIG. 3A, the plurality of power lines PL and the plurality of through insulating patterns 312 may each be disposed on an extension of the cell boundary BN of each of the plurality of cells LC in the first horizontal direction (X direction).

As shown in FIG. 4A, a lower surface of a through insulating pattern 312, which faces the substrate 102, may be in contact with the device isolation layer 112. In the inter-cell separation region FR, the device isolation layer 112 may include a portion arranged between the substrate 102 and the plurality of through insulating patterns 312. In some embodiments, the plurality of dummy gate insulating lines FG and the plurality of through insulating patterns 312 may each include a silicon nitride layer, but embodiments are not limited thereto.

As shown in FIGS. 3A and 4A, a plurality of via power rails VPR may be arranged in the inter-cell separation region FR. As shown in FIG. 3A, the plurality of via power rails VPR are spaced apart from each other in the second horizontal direction (Y direction), and may be arranged in a row along a straight line in the second horizontal direction (Y direction).

As shown in FIG. 4A, each of the plurality of via power rails VPR may extend through one of the plurality of through insulating patterns 312 in the vertical direction (Z direction) in the inter-cell separation region FR and the device isolation layer 112 in the vertical direction (Z direction) to be electrically connected to one of the plurality of power lines PL. Each of the plurality of via power rails VPR may include a metal plug. The metal plug may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, but is not limited thereto. Each of the plurality of via power rails VPR may further include a conductive barrier layer surrounding the metal plug. The conductive barrier layer may include Ti, Ta, W, TiN, TaN, WN, WCN, TiSiN, TaSiN, WSiN, or a combination thereof, but is not limited thereto.

As shown in FIG. 4B, the plurality of source/drain contacts CA may be disposed over the plurality of source/drain regions 130. Each of the plurality of source/drain contacts CA may extend through the inter-gate insulating layer 144 and the insulating liner 142 in the vertical direction (Z direction) to be in contact with the metal silicide layer 172. Each of the plurality of source/drain contacts CA may be electrically connected to the source/drain region 130 through the metal silicide layer 172. Each of the plurality of source/drain contacts CA may include the conductive barrier layer 174 and the contact plug 176, which are sequentially stacked over the source/drain region 130. The conductive barrier layer 174 may be arranged between the metal silicide layer 172 and the contact plug 176.

The upper insulating structure 180 may be arranged in the cell region CR and the inter-cell separation region FR. As shown in FIGS. 4B and 4C, an upper surface of each of the plurality of source/drain contacts CA, the plurality of capping insulating patterns 168 and the inter-gate insulating layer 144 may be covered by the upper insulating structure 180. The upper insulating structure 180 may include the etch stop layer 182 and the upper insulating layer 184. The plurality of source/drain via contacts VA may be disposed on the plurality of source/drain contacts CA. Some of the plurality of source/drain via contacts VA may be in contact with the source/drain contact CA through the upper insulating structure 180. Some others of the plurality of source/drain via contacts VA may be in contact with a via power rail VPR through the upper insulating structure 180. As shown in FIG. 4C, a gate contact CB may be disposed on the gate line 160.

The interlayer insulating layer 186 and the plurality of upper wiring layers M1 penetrating the interlayer insulating layer 186 may be disposed above each of the upper insulating structure 180, the plurality of source/drain via contacts VA and the gate contact CB. Each of the plurality of upper wiring layers M1 may be electrically connected to one selected from among the plurality of source/drain via contacts VA, a plurality of gate contacts CB, and the plurality of via power rails VPR, which are disposed under the plurality of upper wiring layers M1.

As shown in FIG. 4A, a backside power rail MPR penetrating the substrate 102 in the vertical direction (Z direction) from the backside surface 102B of the substrate 102 may be arranged. The backside power rail MPR may be arranged between the via power rail VPR and a power line PL. The backside power rail MPR may include a metal wiring layer and a conductive barrier layer surrounding the metal wiring layer. The metal wiring layer may include Ru, Co, W, or a combination thereof. The conductive barrier layer may include Ti, TiN, Ta, TaN, or a combination thereof. An insulating layer 306 may be arranged between the substrate 102 and the backside power rail MPR. The insulating layer 306 may include a silicon oxide layer, a silicon nitride layer, or a combination thereof.

As shown in FIGS. 4B and 4C, the backside surface 102B of the substrate 102 may be covered by the backside insulating layer 109. Each of the plurality of power lines PL may penetrate the backside insulating layer 109 in the vertical direction (Z direction) and may be in contact with one end of the backside power rail MPR. Each of the plurality of via power rails VPR may be connected to the power line PL through the backside power rail MPR.

A vertical level of a lower surface of each of a plurality of trench regions T1 in the memory region 11 shown in FIGS. 2A to 2C and a vertical level of a lower surface of each of a plurality of trench regions T1 in the logic region 13 shown in FIGS. 3A, 3B, and 4A to 4C may each be the same as or similar to a first vertical level LV1. In addition, in the logic region 13 shown in FIGS. 3A, 3B, and 4A to 4C, a vertical level of a lower surface of each of the plurality of trench regions T1 in the cell region CR and a vertical level of a lower surface of (the trench region T1 in the inter-cell separation region FR may each be the same as or similar to the first vertical level LV1. Herein, the expression “similar to the first vertical level LV1” refers to a vertical level within an error range of about 0 nm to about 1 nm from the first vertical level LV1.

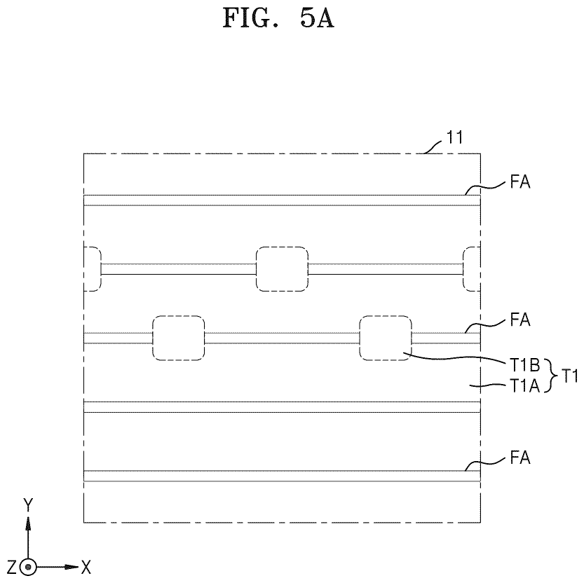

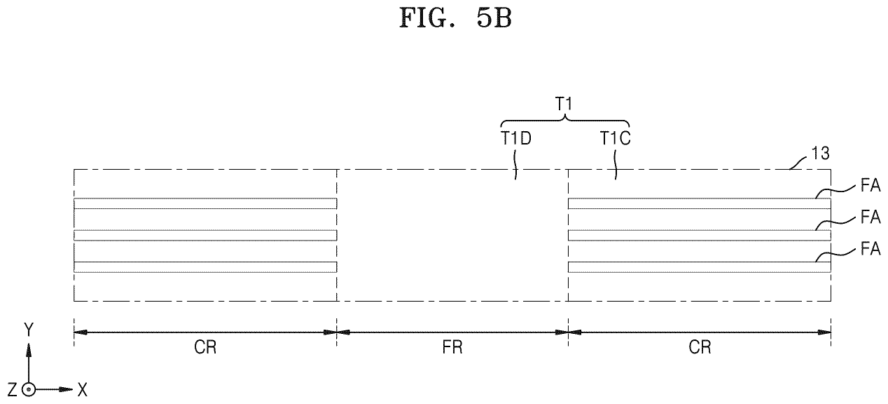

FIG. 5A is a plan view of a plurality of fin-type active regions defined by a trench region in a memory region of an integrated circuit device, according to an embodiment.

FIG. 5B is a plan view of a plurality of fin-type active regions defined by a trench region in a logic region of an integrated circuit device, according to an embodiment.

As shown in FIG. 5A, in the memory region 11, the plurality of trench regions T1 may include: a first local trench region T1A arranged between two fin-type active regions FA spaced apart from each other in the second horizontal direction (Y direction) among the plurality of fin-type active regions FA; and a hole-type trench region T1B arranged between two fin-type active regions FA spaced apart from each other in the first horizontal direction (X direction) among the plurality of fin-type active regions FA.

As shown in FIG. 5B, in the logic region 13, the plurality of trench regions T1 may include: a second local trench region T1C arranged between two fin-type active regions FA spaced apart from each other in the second horizontal direction (Y direction) among the plurality of fin-type active regions FA; and a line-type trench region T1D arranged between two fin-type active regions FA spaced apart from each other in the first horizontal direction (X direction) among the plurality of fin-type active regions FA and extending long in the second horizontal direction (Y direction) in the inter-cell separation region FR.

A vertical level of a lower surface of each of the first local trench region T1A and the hole-type trench region T1B in the memory region 11 and a vertical level of a lower surface of each of the second local trench region T1C and the line-type trench region T1D in the logic region 13 may be the same as or similar to the first vertical level LV1 described with reference to FIGS. 2A to 4C.

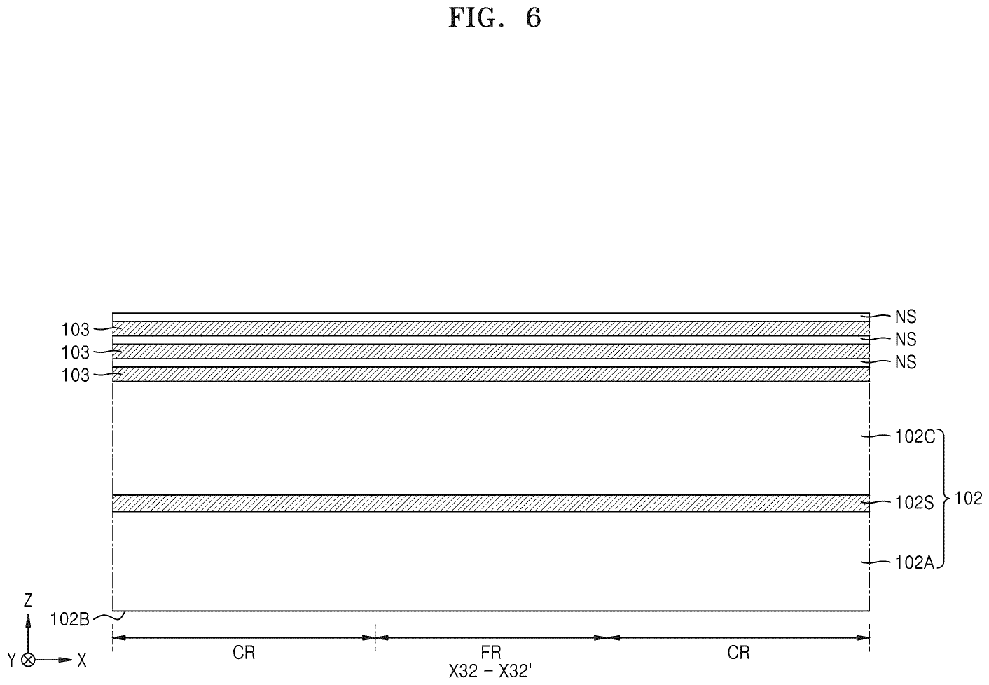

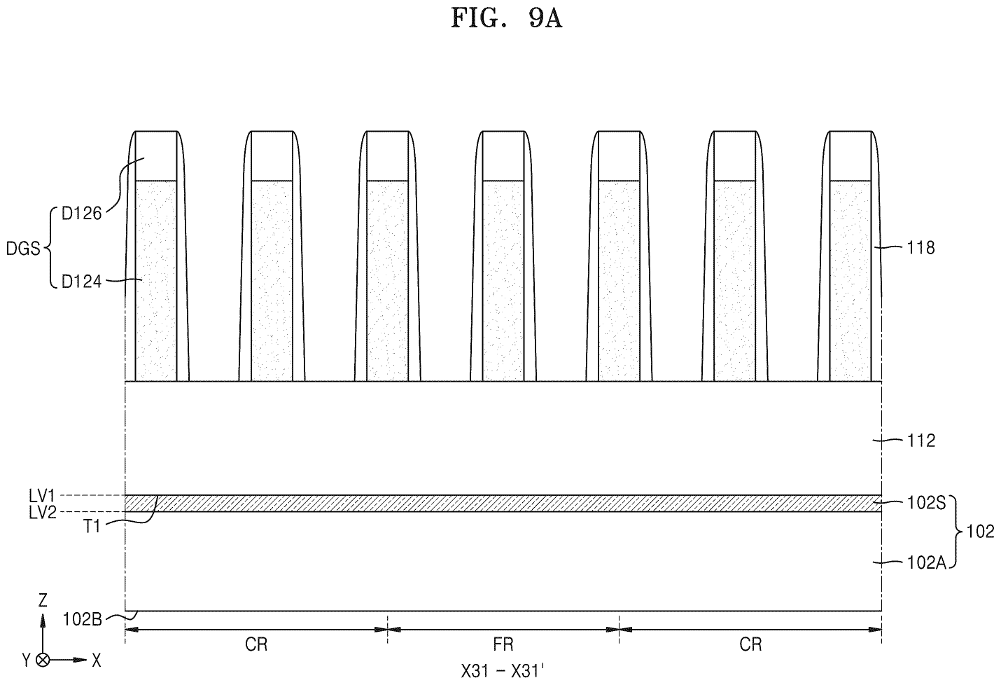

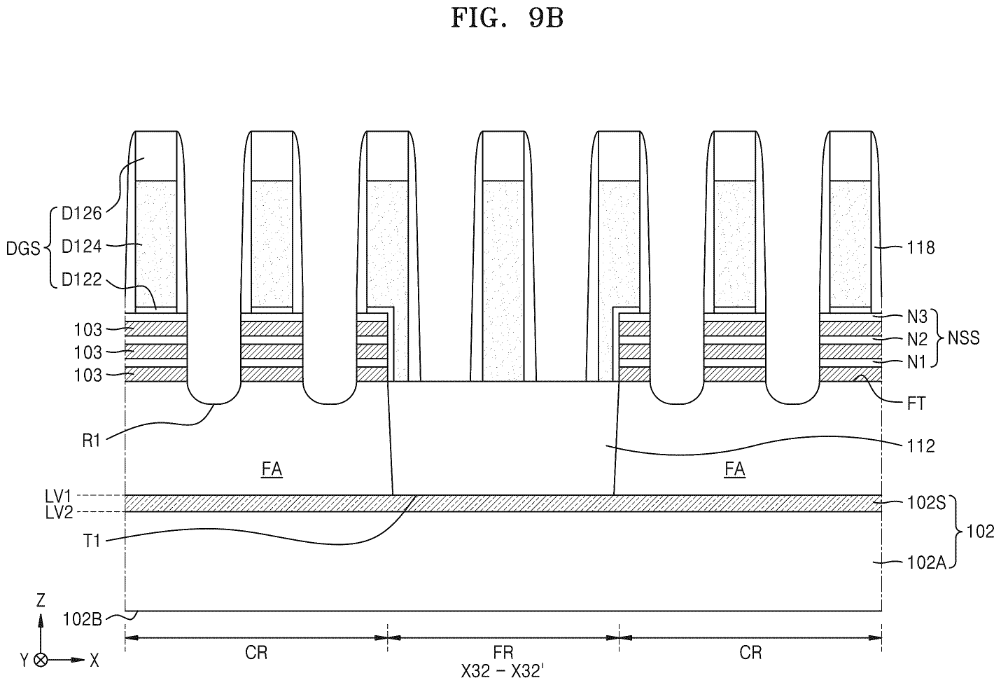

FIGS. 6 to 16B are shown according to a process sequence to explain an example method of manufacturing an integrated circuit device, according to embodiments. More specifically, FIGS. 9A, 10A, 11A, 12A, 13A, 14A, 15A, and 16A are enlarged cross-sectional views of some configurations according to a process sequence in a portion corresponding to a cross-section taken along a line X31-X31′ of FIG. 3A. FIGS. 6, 7, 8, 9B, 10B, 11B, 12B, 13B, 14B, 15B, and 16B are enlarged cross-sectional views of some configurations according to a process sequence in a portion corresponding to a cross-section taken along a line X32-X32′ of FIG. 3A.

Referring to FIGS. 6 to 16B, a method of manufacturing an integrated circuit device, according to some embodiments, is described. Processes in the logic region 13 are described with reference to FIGS. 6 to 16B, but unless otherwise described herein, it should be understood that the same or similar processes as those in the logic region 13 are also performed in the memory region 11.

Referring to FIG. 6, the substrate 102 including the memory region 11 and the logic region 13 is prepared. At this time, the substrate 102 may be a semiconductor on insulator (SOI) substrate in which the base substrate layer 102A, the insulating substrate layer 102S, and a cover substrate layer 102C are sequentially stacked.

The base substrate layer 102A may include a semiconductor material such as Si or Ge, or a compound semiconductor material such as SiGe, SiC, GaAs, InAs, or InP. In some embodiments, the base substrate layer 102A may include at least one of a Group III-V material and a Group IV material.

The insulating substrate layer 102S may include an insulating material. The insulating substrate layer 102S may include, for example, silicon oxide (SiOx), silicon nitride (SIN), or a combination thereof. However, embodiments are not limited thereto, and the insulating substrate layer 102S may include one insulating layer of silicon oxynitride (SiON), germanium oxide (GeOx), germanium nitride (GeNx), aluminum oxide (Al₂O₃), tantalum oxide (Ta₂O₅), hafnium oxide (HfO₂), and aluminum nitride (AlN), or a structure of a stack of at least two insulating layers thereof. The insulating substrate layer 102S may have a thickness of several tens of nm. For example, the insulating substrate layer 102S may have a thickness of about 10 nm to about 20 nm. An upper surface of the insulating substrate layer 102S may be the same as or similar to the first vertical level LV1, and a lower surface of the insulating substrate layer 102S may be the same as or similar to a second vertical level LV2.

The cover substrate layer 102C may include a semiconductor material such as Si or Ge, or a compound semiconductor material such as SiGe, SiC, GaAs, InAs, or InP. In some embodiments, the cover substrate layer 102C may include a semiconductor material that is different from that of the base substrate layer 102A. For example, the base substrate layer 102A may include Si, and the cover substrate layer 102C may include any one of Group III-V materials described above.

Afterwards, a plurality of sacrificial semiconductor layers 103 and a plurality of nanosheet semiconductor layers NS may be alternately stacked one layer at a time to form a stacked structure. In the logic region 13, the plurality of sacrificial semiconductor layers 103 and the plurality of nanosheet semiconductor layers NS may be stacked on a front surface of the substrate 102 having the plurality of cell regions CR and the inter-cell separation region FR arranged between the plurality of cell regions CR.

The plurality of sacrificial semiconductor layers 103 and the plurality of nanosheet semiconductor layers NS may include semiconductor materials having different etch selectivities. In some embodiments, the plurality of sacrificial semiconductor layers 103 may include a SiGe layer, and the plurality of nanosheet semiconductor layers NS may include a Si layer.

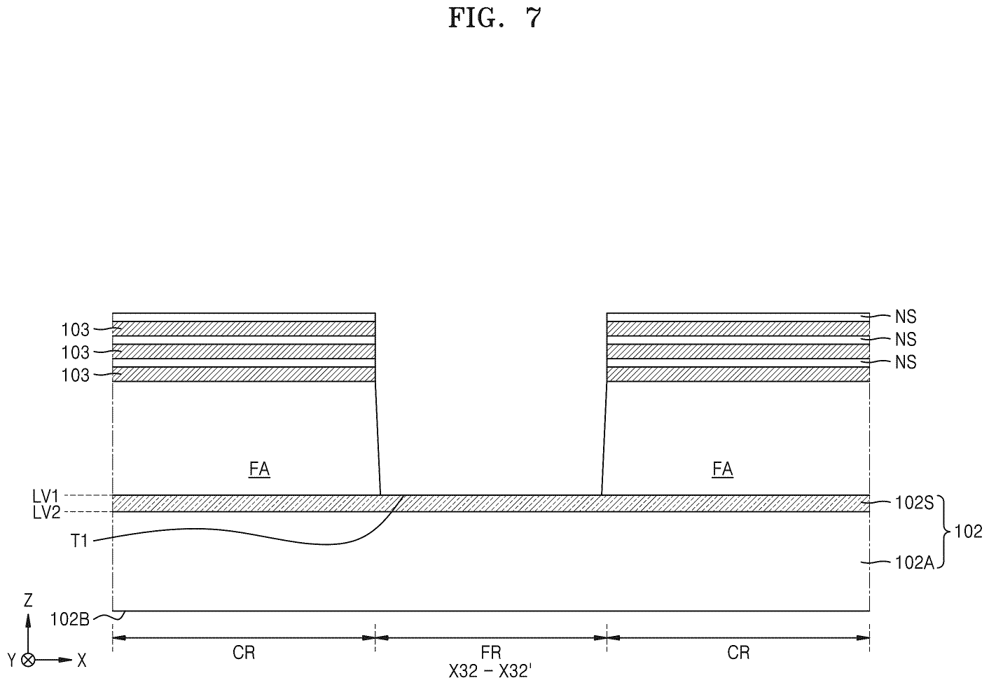

Referring to FIG. 7, a mask pattern may be used as an etch mask to etch portions of the stacked structure and the substrate 102 to form the plurality of fin-type active regions FA. Specifically, the plurality of fin-type active regions FA may be formed on the substrate 102 in each of the plurality of cell regions CR by etching portions of the plurality of sacrificial semiconductor layers 103, the plurality of nanosheet semiconductor layers NS and the cover substrate layer 102C. Because the plurality of fin-type active regions FA are formed, the plurality of trench regions T1 may be defined on the substrate 102 in the plurality of cell regions CR and the inter-cell separation region FR. At this time, the mask pattern may include hole openings corresponding to the hole-type trench region T1B (see FIG. 5A) in the memory region 11, and line openings corresponding to the line-type trench region T1D (see FIG. 5B) in the logic region 13.

In some embodiments, the mask pattern may include a stacked structure of an oxide layer pattern and a silicon nitride layer pattern. The plurality of fin-type active regions FA may be formed to extend parallel to each other and extend long in the first horizontal direction (X direction). The stacked structure of the plurality of sacrificial semiconductor layers 103 and the plurality of nanosheet semiconductor layers NS may remain on an upper surface of each of the plurality of fin-type active regions FA.

In some embodiments, the plurality of fin-type active regions FA may be formed on the insulating substrate layer 102S. A vertical level of a bottom surface of each of the plurality of trench regions T1 and a vertical level of an upper surface of the insulating substrate layer 102S may each be the same as or similar to the first vertical level LV1. In forming the plurality of fin-type active regions FA by etching a portion of the cover substrate layer 102C, the insulating substrate layer 102S may act as an etch stop layer. In this regard, portions of the stacked structure and the cover substrate layer 102C may be etched in a vertical direction up to an upper surface of the insulating substrate layer 102S. The plurality of trench regions T1 may be formed by controlling an etching process atmosphere such that the insulating substrate layer 102S exposed through the hole openings and the line openings is not etched.

Therefore, when the plurality of trench regions T1 are formed, depth loading in which a lower-surface level of each of the plurality of trench regions T1 becomes inconsistent is not caused, and a vertical level of a lower surface of each of the plurality of trench regions T1 in the memory region 11 and a vertical level of a lower surface of each of the plurality of trench regions T1 in the logic region 13 may each be the same as or similar to the first vertical level LV1. In addition, in the logic region 13, a vertical level of a lower surface of each of the plurality of trench regions T1 in the cell region CR and a vertical level of a lower surface of the trench region T1 in the inter-cell separation region FR may be the same as or similar to the first vertical level LV1.

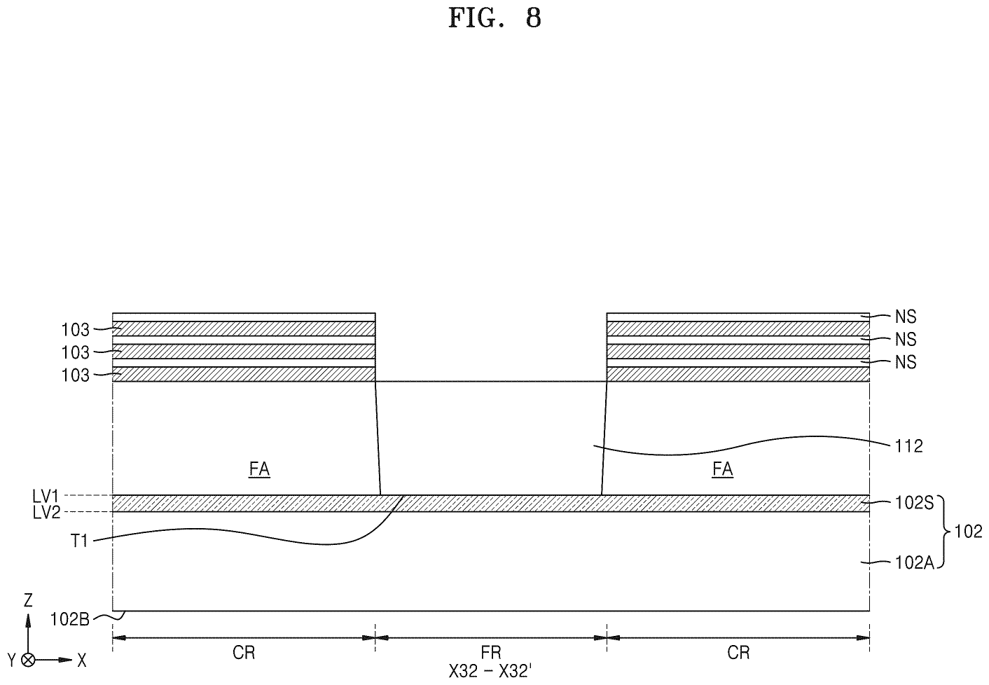

Referring to FIG. 8, in the memory region 11 and the logic region 13, the device isolation layer 112 that fills the trench region T1 between each of the plurality of fin-type active regions FA may be formed. After the device isolation layer 112 is formed, the plurality of sacrificial semiconductor layers 103 and the plurality of nanosheet semiconductor layers NS may protrude above an upper surface of the device isolation layer 112. The device isolation layer 112 may include a silicon oxide layer, but is not limited thereto. In order to form the device isolation layer 112, plasma enhanced chemical vapor deposition (PECVD), high density plasma CVD (HDP CVD), inductively coupled plasma CVD (ICP CVD), capacitor coupled plasma CVD (CCP CVD), flowable chemical vapor deposition (FCVD), and spin coating processes, etc. may be used.

At this time, a vertical level of a lower surface of the plurality of fin-type active regions FA, a vertical level of the device isolation layer 112, and an upper surface of the insulating substrate layer 102S may each be the same as or similar to the first vertical level LV1.

Referring to FIGS. 9A and 9B, a plurality of dummy gate structures DGS may be formed in the memory region 11 and the logic region 13. In the logic region 13, the plurality of dummy gate structures DGS may be formed in the plurality of cell regions CR and the inter-cell separation region FR. Each of the plurality of dummy gate structures DGS may have a structure in which an oxide layer D122, a dummy gate layer D124, and a capping layer D126 are sequentially stacked. The dummy gate layer D124 may include polysilicon, and the capping layer D126 may include a silicon nitride layer.

The plurality of outer insulating spacers 118 covering both sidewalls of each of the plurality of dummy gate structures DGS may be formed. Portions of each of the plurality of sacrificial semiconductor layers 103 and the plurality of nanosheet semiconductor layers NS and a portion of the fin-type active region FA may be selectively etched by using the plurality of dummy gate structures DGS and the plurality of outer insulating spacers 118 as an etching mask, to divide the plurality of nanosheet semiconductor layers NS into the plurality of nanosheet stacks NSS each including the first nanosheet N1, the second nanosheet N2, and the third nanosheet N3, and to form the plurality of recesses R1 above the plurality of fin-type active regions FA. Dry etching, wet etching, or a combination thereof may be used to form the plurality of nanosheet stacks NSS and the plurality of recesses R1.

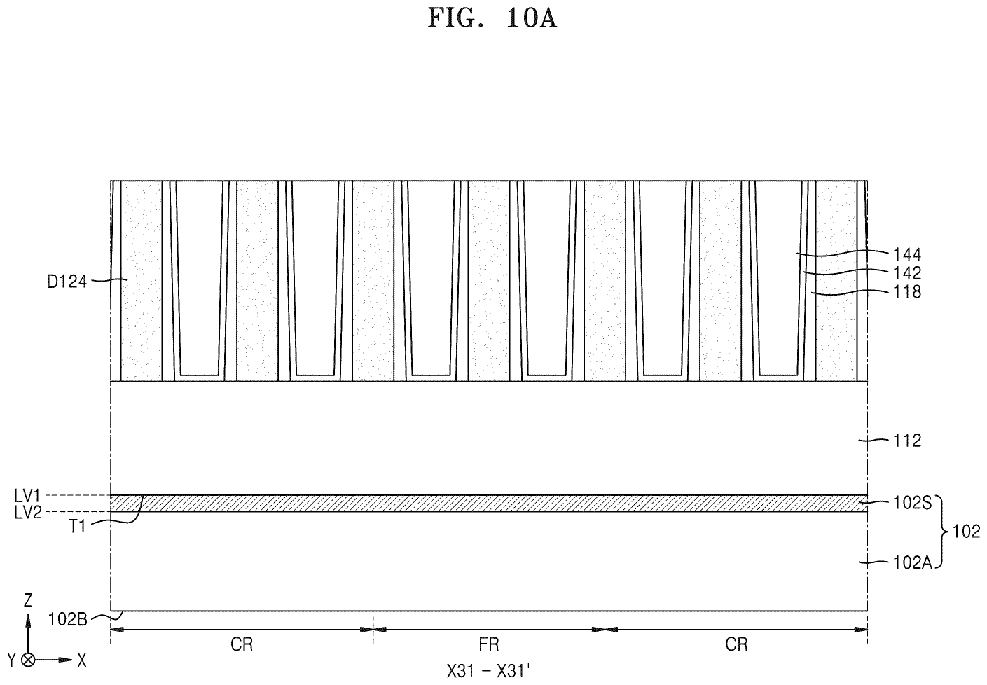

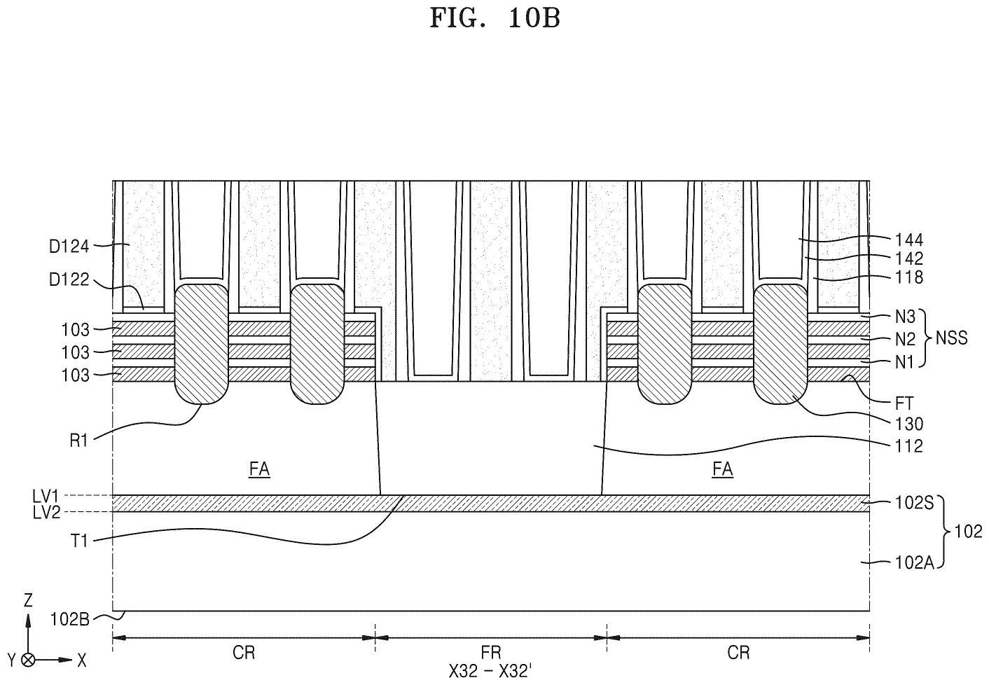

Referring to FIGS. 10A and 10B, in the results of FIGS. 9A and 9B, the plurality of source/drain regions 130 that fill the plurality of recesses R1 may be formed. In order to form the plurality of source/drain regions 130, a semiconductor material may be epitaxially grown from a surface of the fin-type active region FA exposed through lower surfaces of the plurality of recesses RI and from a sidewall of each of the first nanosheet N1, the second nanosheet N2, and the third nanosheet N3, which are included in the nanosheet stack NSS.

Afterwards, the insulating liner 142 covering a result in which the plurality of source/drain regions 130 may be formed, the inter-gate insulating layer 144 may be formed on the insulating liner 142, and then portions of each of the insulating liner 142 and the inter-gate insulating layer 144 may be etched to expose upper surfaces of a plurality of capping layers D126. Afterwards, the plurality of capping layers D126 may be removed to expose the dummy gate layer D124, and the insulating liner 142 and the inter-gate insulating layer 144 may be partially removed such that an upper surface of the inter-gate insulating layer 144 and an upper surface of the dummy gate layer D124 are at substantially the same level.

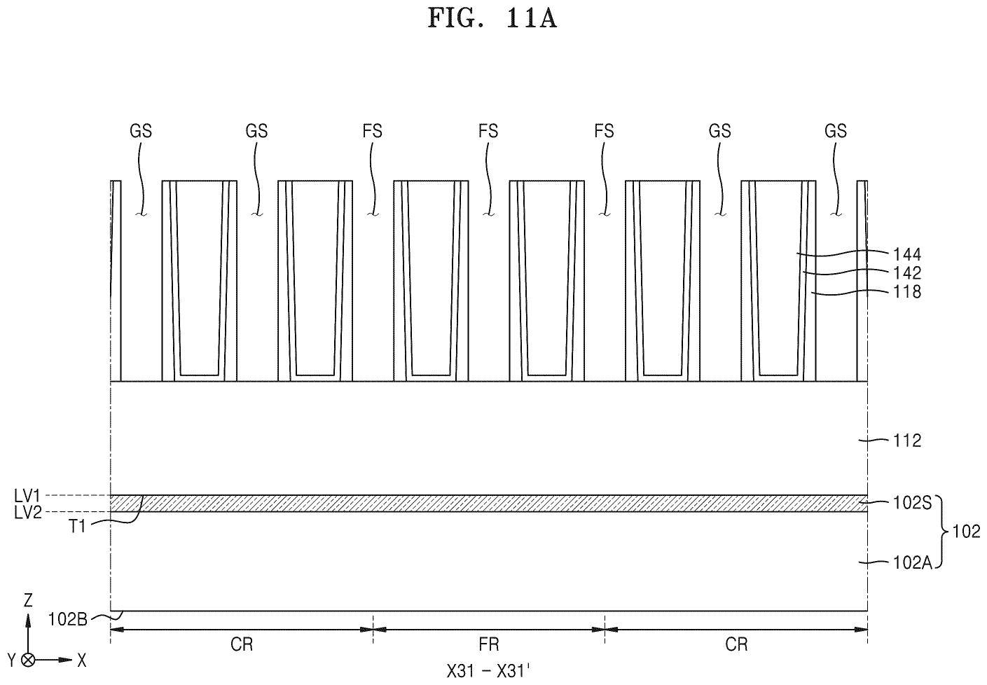

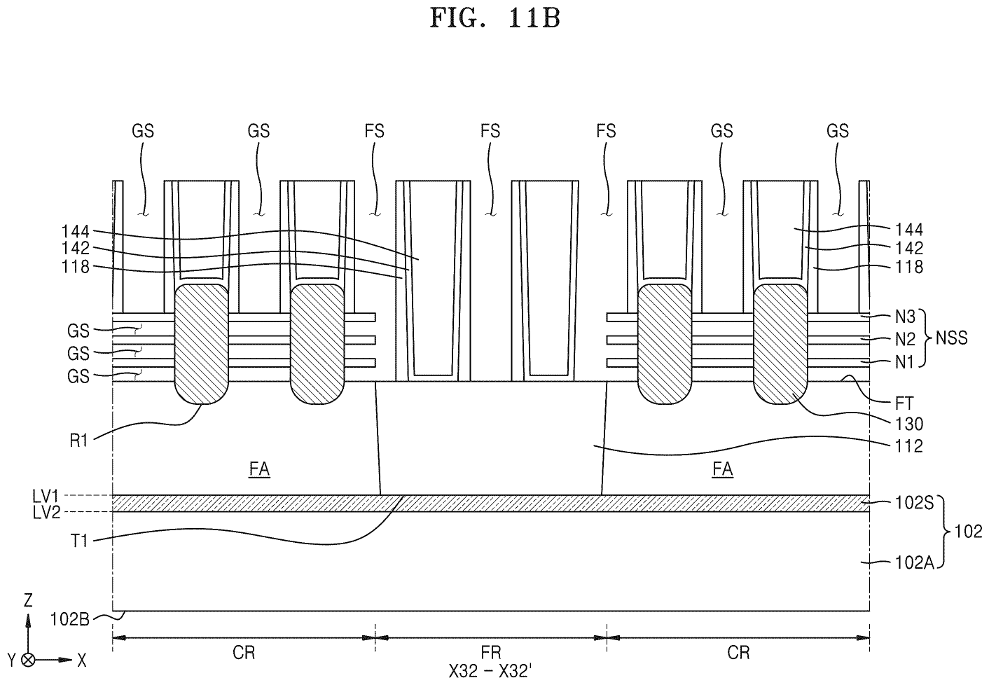

Referring to FIGS. 11A and 11B, the dummy gate layer D124 and the oxide layer D122 therebelow may be removed from the results of FIGS. 10A and 10B, and then the plurality of sacrificial semiconductor layers 103 remaining on the fin-type active region FA may be selectively removed through spaces in which the dummy gate layer D124 and the oxide layer D122 are removed. In some embodiments, in order to selectively remove the plurality of sacrificial semiconductor layers 103, a difference in etch selectivity between the first nanosheet N1, the second nanosheet N2, and the third nanosheet N3 and the plurality of sacrificial semiconductor layers 103 may be used. A liquid or vapor phase etchant may be used to selectively remove the plurality of sacrificial semiconductor layers 103. In some embodiments, in order to selectively remove the plurality of sacrificial semiconductor layers 103, CH₃COOH-based etchant, for example, an etchant including a mixture of CH₃COOH, HNO₃, and HF, or an etchant including CH₃COOH, H₂O₂, and HF, may be used, but is not limited to the above examples.

After the plurality of sacrificial semiconductor layers 103 are selectively removed, a plurality of gate spaces GS extending long in the second horizontal direction (Y direction) are formed in the cell region CR of the memory region 11 and the logic region 13, and the plurality of nanosheet stacks NSS may be exposed through the plurality of gate spaces GS. A plurality of dummy gate spaces FS extending long in the second horizontal direction (Y direction) may be formed in the inter-cell separation region FR of the logic region 13, and an upper surface of the device isolation layer 112 may be exposed through the plurality of dummy gate spaces FS. In a dummy gate space FS, which passes through a boundary portion between the inter-cell separation region FR and the cell region CR, among the plurality of dummy gate spaces FS, pieces of the first nanosheet N1, the second nanosheet N2 and the third nanosheet N3 remaining on an end portion of the fin-type active region FA, the end portion being adjacent to the inter-cell separation region FR, and an upper surface of the device isolation layer 112 may be exposed together.

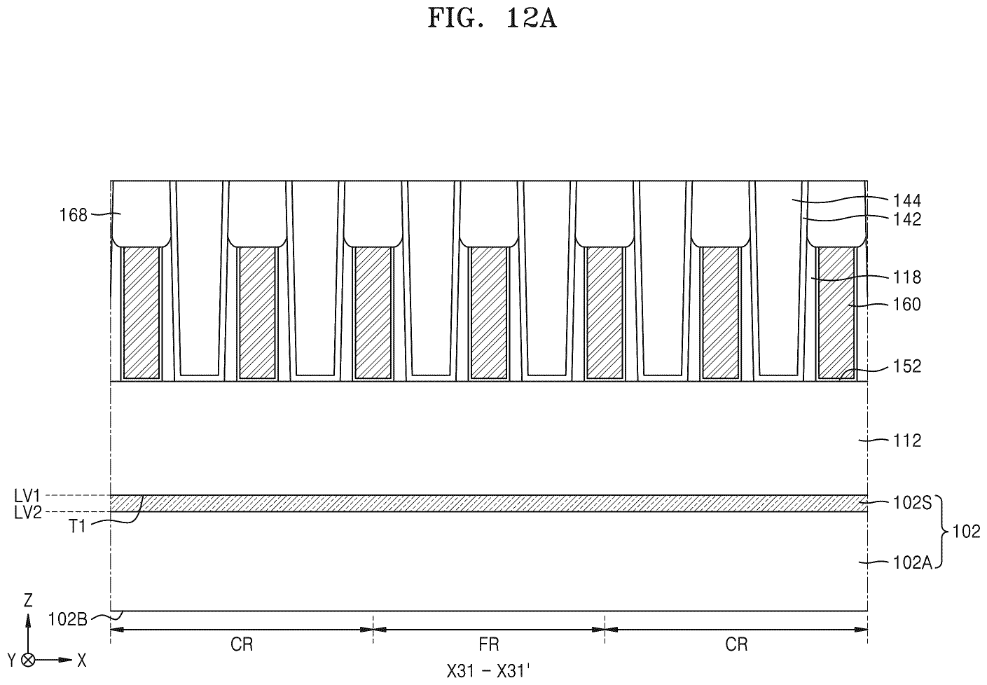

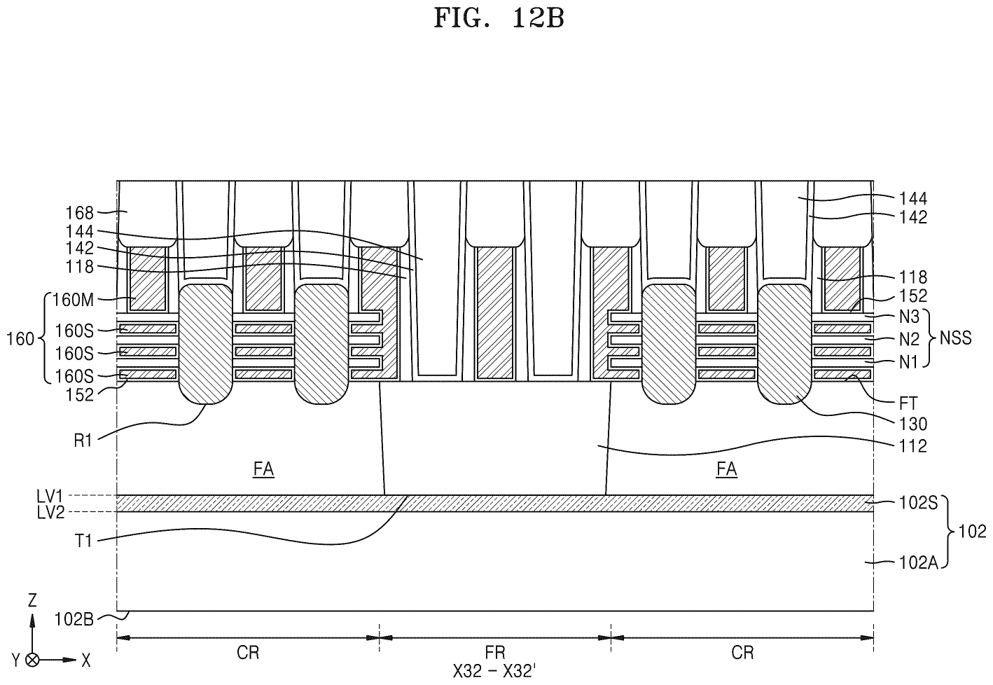

Referring to FIGS. 12A and 12B, the gate dielectric layer 152 covering surfaces exposed through the plurality of gate spaces GS and the plurality of dummy gate spaces FS in the results of FIGS. 11A and 11B may be formed in the memory region 11 and the logic region 13. An atomic layer deposition (ALD) process may be used to form the gate dielectric layer 152.

Afterwards, the gate line 160 that fills portions of each of the plurality of gate spaces GS and the plurality of dummy gate spaces FS may be formed on the gate dielectric layer 152, and the capping insulating pattern 168 covering an upper surface of each of the gate line 160 and the gate dielectric layer 152 may be formed in each of the plurality of gate spaces GS and the plurality of dummy gate spaces FS.

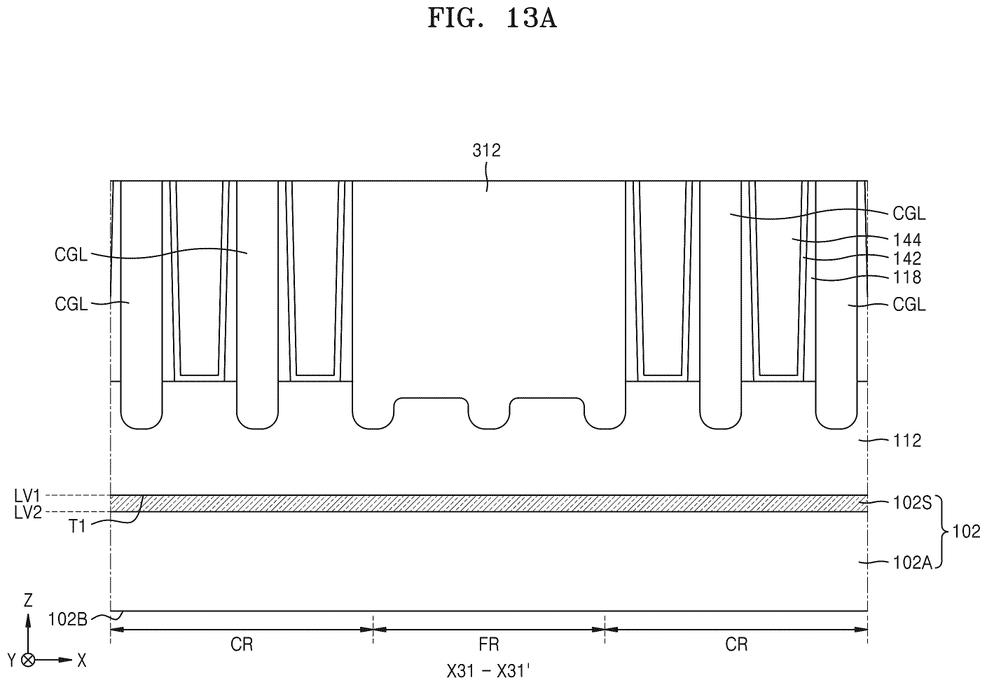

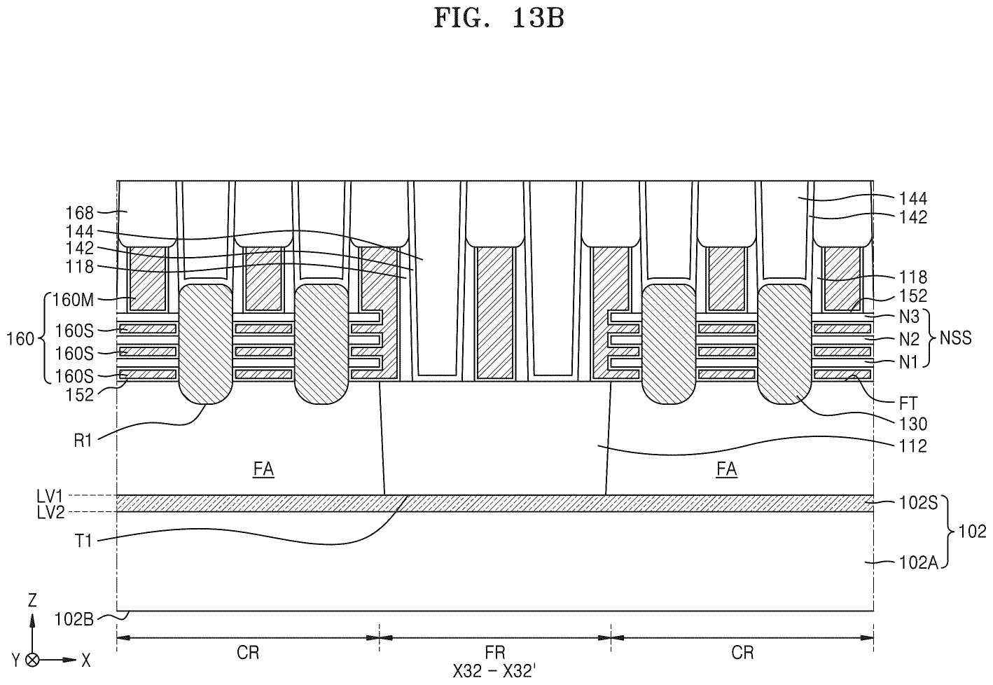

Referring to FIGS. 13A and 13B, the plurality of gate cut insulating patterns CGL may be formed by replacing the gate line 160, the gate dielectric layer 152, and the capping insulating pattern 168 with an insulating material in the cell boundary BN of each of a pair of cells LC in the first horizontal direction (X direction), which are adjacent to each other in the second horizontal direction (Y direction), and cut regions selected along an extension of the cell boundary BN in the logic region 13 in the results of FIGS. 12A and 12B, and the plurality of through insulating patterns 312 may be formed in the inter-cell separation region FR.

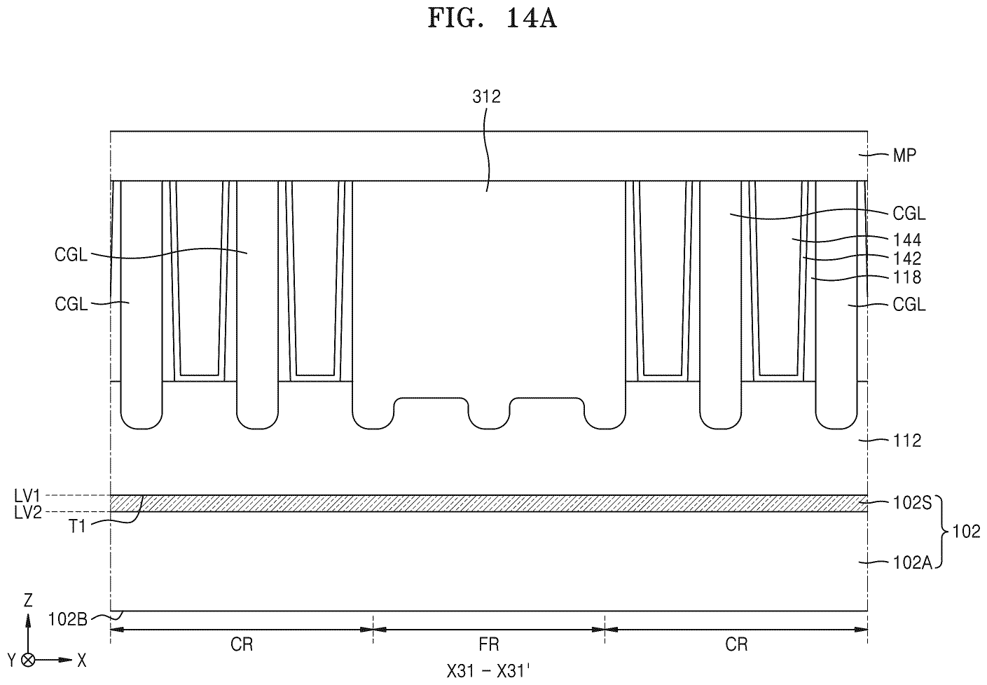

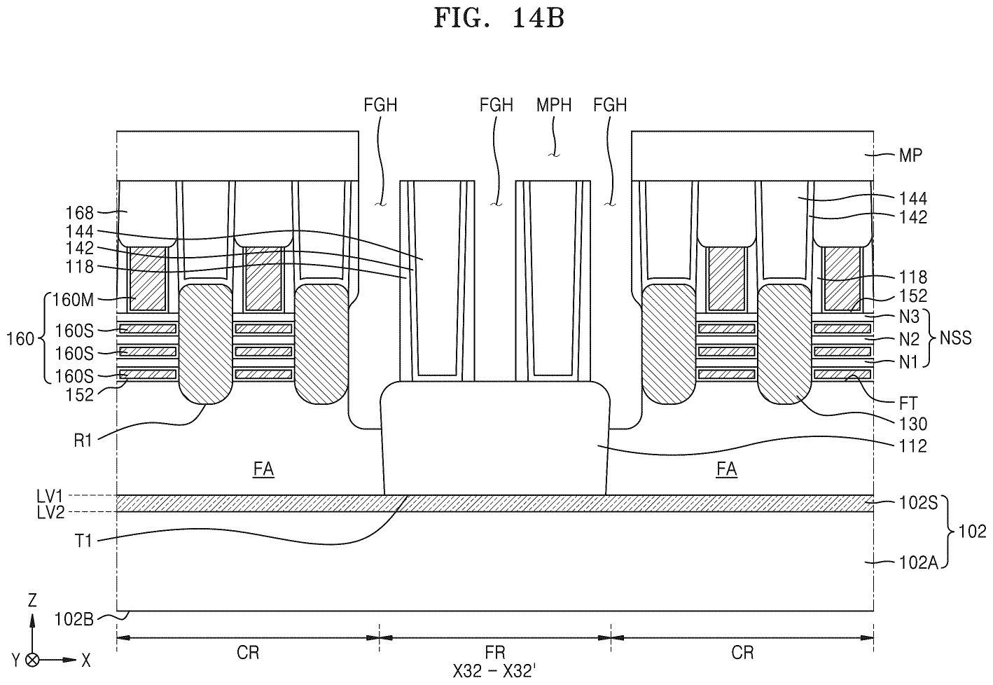

Referring to FIGS. 14A and 14B, a mask pattern MP having an opening MPH that exposes a partial region of the inter-cell separation region FR of the logic region 13 and a partial region including the cell boundary BN (see FIG. 3A) of each of the plurality of cells LC adjacent to the inter-cell separation region FR may be formed. Afterwards, by using the mask pattern MP as an etch mask, in a partial region including the inter-cell separation region FR and the cell boundary BN (see FIG. 3A) of each of the plurality of cells LC adjacent to the inter-cell separation region FR, a plurality of dummy insulating spaces FGH may be formed by removing the plurality of capping insulating patterns 168, the plurality of gate lines 160, and a plurality of gate dielectric layers 152 through the opening MPH.

In some embodiments, due to an etching atmosphere for removing the plurality of capping insulating patterns 168, the plurality of gate lines 160, and the plurality of gate dielectric layers 152 in order to form the plurality of dummy insulating spaces FGH, pieces of the first nanosheet N1, the second nanosheet N2 and the third nanosheet N3 remaining on an end portion of the fin-type active region FA, the end portion being adjacent to the inter-cell separation region FR, and a portion of the fin-type active region FA may be removed together through a dummy insulating space FGH, which passes through a boundary portion between the inter-cell separation region FR and the cell region CR, among the plurality of dummy insulating spaces FGH.

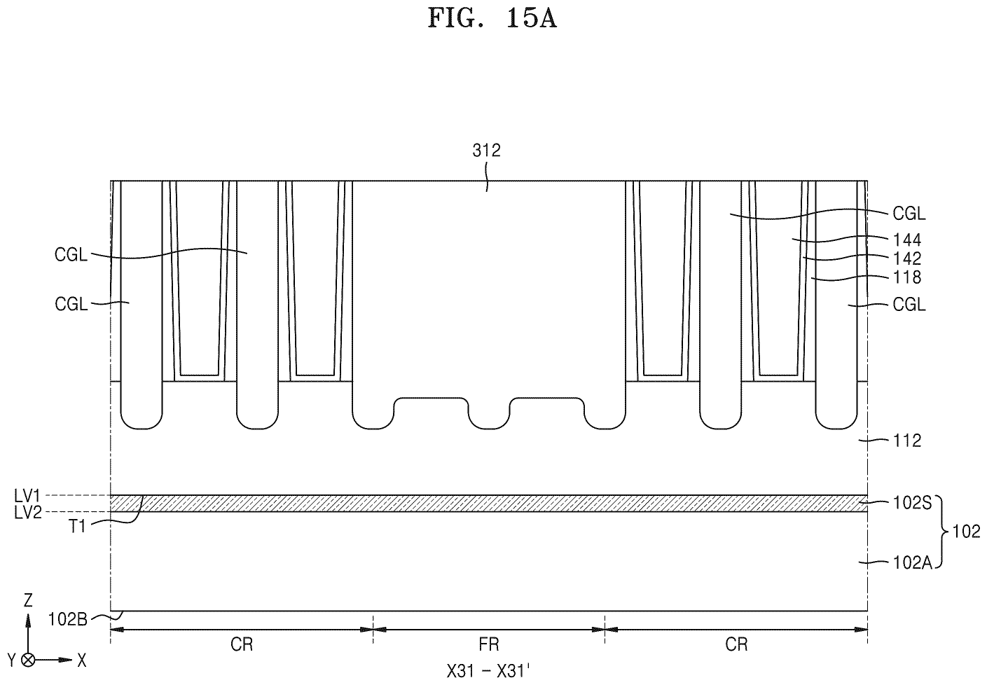

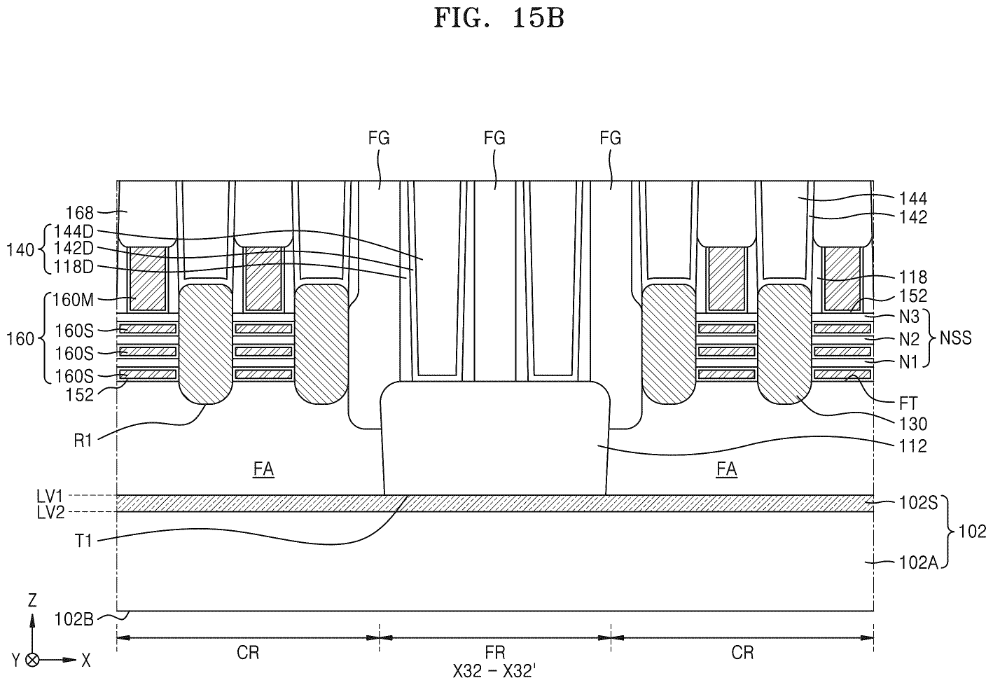

Referring to FIGS. 15A and 15B, the mask pattern MP is removed from the results of FIGS. 14A and 14B, and the plurality of dummy gate insulating lines FG that fill the plurality of dummy insulating spaces FGH may be formed. The plurality of dummy gate insulating lines FG may include a silicon nitride layer, but is not limited thereto.

After the plurality of dummy gate insulating lines FG are formed, the outer insulating spacer 118, the insulating liner 142, and the inter-gate insulating layer 144, which remain between each of the plurality of dummy gate insulating lines FG in the inter-cell separation region FR, may constitute the dummy insulating structure 140.

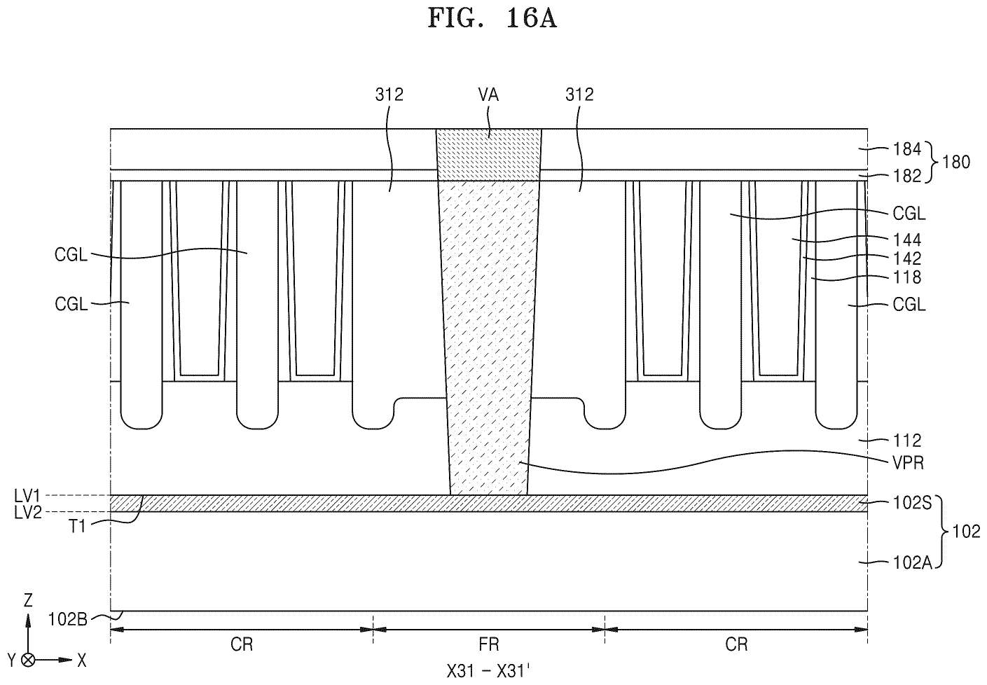

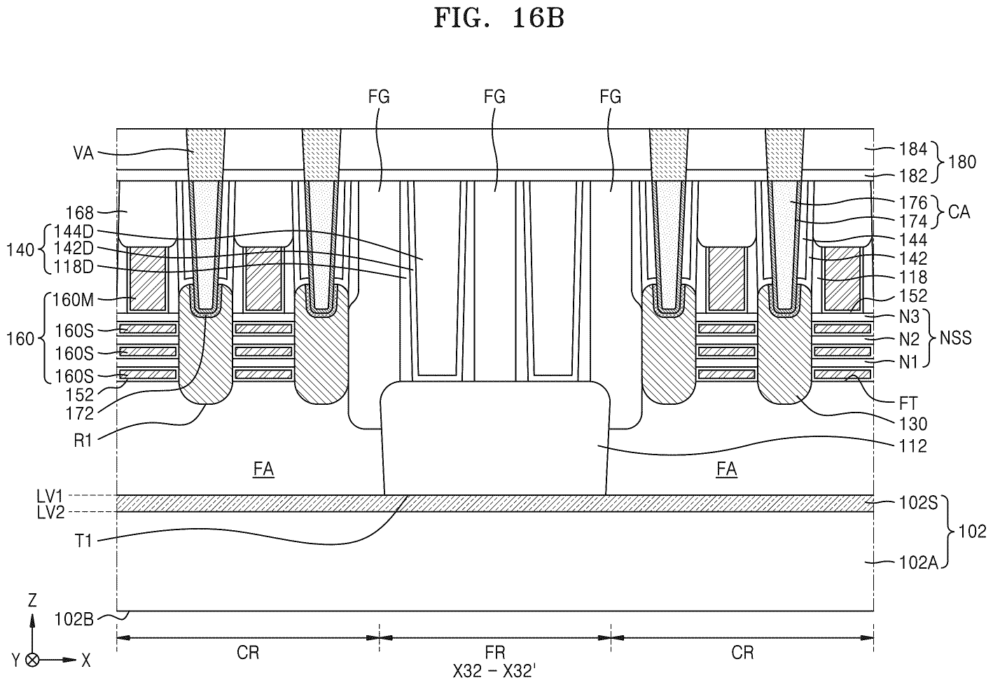

Referring to FIGS. 16A and 16B, after a source/drain contact hole is formed to expose the source/drain region 130 by penetrating the insulating liner 142 and the inter-gate insulating layer 144 in the vertical direction (Z direction) in the plurality of cell regions CR in the memory region 11 and the logic region 13, a partial region of the source/drain region 130 may be removed by an anisotropic etching process through the source/drain contact hole, thereby allowing the drain/source contact hole to extend longer toward the substrate 102. Afterwards, the metal silicide layer 172 may be formed on the source/drain region 130 exposed through a bottom side of the source/drain contact hole. Afterwards, the source/drain contact CA including the conductive barrier layer 174 and the contact plug 176 may be formed on the metal silicide layer 172.

The etch stop layer 182 and the upper insulating layer 184 may be sequentially formed on exposed surfaces on the substrate 102 to form the upper insulating structure 180. Afterwards, the plurality of source/drain via contacts VA connected to the plurality of source/drain contacts CA by penetrating the upper insulating structure 180 in the vertical direction (Z direction) and the gate contact CB (see FIG. 4C) connected to the gate line 160 by penetrating the upper insulating structure 180 and the capping insulating pattern 168 in the vertical direction (Z direction) may be formed.

The plurality of via power rails VPR penetrating the upper insulating structure 180, the plurality of through insulating patterns 312, and the device isolation layer 112 in the vertical direction may be formed in the inter-cell separation region FR of the logic region 13. At this time, a vertical level of a lower surface of the via power rail VPR and a vertical level of an upper surface of the insulating substrate layer 102S may each be the same as or similar to the first vertical level LV1. An order for forming the source/drain via contact VA, the gate contact CB, and the via power rail VPR is not particularly limited.

Afterwards, as shown in FIGS. 2B, 2C, and 4A to 4C, the interlayer insulating layer 186 covering the upper insulating structure 180 and the via power rail VPR and the plurality of upper wiring layers M1 connected to each of the source/drain via contact VA, the gate contact CB and the via power rail VPR through the interlayer insulating layer 186 may be formed.

Afterwards, the thickness of the substrate 102 in the vertical direction (Z direction) may be reduced by removing a portion of the substrate 102 from the backside surface 102B of the substrate 102 in the memory region 11 and the logic region 13. In order to reduce the thickness of the substrate 102 in the vertical direction (Z direction), at least one process selected from a mechanical grinding process, a chemical mechanical polishing (CMP) process, a wet etching process, and a combination thereof may be used. As a result, the exposed backside surface 102B of the substrate 102 may be closer to the device isolation layer 112.

At this time, as described above, by using the substrate 102 including the insulating substrate layer 102S, a vertical level of a lower surface of each of the plurality of trench regions T1 in the memory region 11 and a vertical level of a lower surface of each of the plurality of trench regions T1 in the logic region 13 may be the same as or similar to the first vertical level LV1. Therefore, after the thickness of the substrate 102 is reduced from the backside surface 102B of the substrate 102, the thickness of the substrate 102 remaining on a lower surface of the insulating substrate layer 102S may be substantially constant throughout the memory region 11 and the logic region 13. The thickness from the second vertical level LV2 of a lower surface of the insulating substrate layer 102S to the exposed backside surface 102B of the substrate 102 may be substantially constant throughout the memory region 11 and the logic region 13.

Afterwards, as shown in FIG. 4A, the insulating layer 306 penetrating the substrate 102 in the vertical direction (Z direction) and the backside power rail MPR being in contact with one end of the via power rail VPR by penetrating the substrate 102 in the vertical direction (Z direction) may be formed in the logic region 13. The backside power rail MPR may be formed to be in contact with one end of the via power rail VPR by penetrating the insulating substrate layer 102S in the vertical direction (Z direction).

Afterwards, as shown in FIGS. 2B, 2C, 4B, and 4C, the backside insulating layer 109 covering the backside surface 102B of the substrate 102 and the backside power rail MPR may be formed, and the power line PL that is in contact with one end of the backside power rail MPR by penetrating the backside insulating layer 109 in the vertical direction (Z direction) may be formed.

In forming the backside power rail MPR, the thickness of the substrate 102 remaining on a lower surface of the insulating substrate layer 102S is substantially constant throughout the memory region 11 and the logic region 13, and thus, the thickness of each of a plurality of backside power rails MPR formed through the substrate 102 in the vertical direction (Z direction) may be substantially constant regardless of the position of the substrate 102. As such, according to embodiments, thickness deviations of the plurality of backside power rails MPR are minimized, making it possible to implement a stable electrically connected structure using the plurality of backside power rails MPR.

While aspects of embodiments have been particularly shown and described, it will be understood that various changes in form and details may be made therein without departing from the spirit and scope of the following claims.

What is claimed is:

1. A method of manufacturing an integrated circuit device, the method comprising:
providing a substrate comprising a base substrate layer, an insulating substrate layer, and a cover substrate layer that are sequentially stacked in a vertical direction;
forming, on the substrate, a stacked structure comprising a plurality of sacrificial semiconductor layers and a plurality of nanosheet semiconductor layers that are alternately stacked one layer at a time; and
forming a plurality of trench regions to define a plurality of fin-type active regions by etching the stacked structure and the substrate,
wherein the forming of the plurality of trench regions comprises, by using the insulating substrate layer as an etch stop layer, etching portions of the stacked structure and the cover substrate layer in the vertical direction up to an upper surface of the insulating substrate layer.

2. The method of claim 1, wherein a lower surface of each of the plurality of trench regions and the upper surface of the insulating substrate layer are provided at a same vertical level.

3. The method of claim 1, wherein the insulating substrate layer comprises silicon oxide (SiOx), silicon nitride (SIN), or a combination thereof.

4. The method of claim 3, wherein each of the base substrate layer and the cover substrate layer comprises a semiconductor material.

5. The method of claim 1, wherein the substrate comprises a memory region and a logic region, and
wherein the forming of the plurality of trench regions comprises, by using an etch mask defining hole openings in the memory region and line openings in the logic region, forming the plurality of trench regions defining the plurality of fin-type active regions by etching the stacked structure and the substrate.

6. The method of claim 5, wherein lower surfaces of the plurality of trench regions in the memory region and the logic region are provided at a same vertical level.

7. The method of claim 5, wherein the forming of the plurality of trench regions comprises controlling an etching process atmosphere such that the insulating substrate layer exposed through the hole openings and the line openings is not etched.

8. The method of claim 5, further comprising:
forming a device isolation layer in the plurality of trench regions between the plurality of fin-type active regions;
forming a via power rail penetrating the device isolation layer in the vertical direction;
removing a portion of the substrate from a backside surface of the substrate; and
forming a backside power rail penetrating the substrate in the vertical direction in the logic region and contacting an end of the via power rail,
wherein the backside power rail penetrates the insulating substrate layer, and has a vertical thickness that is constant in the memory region and the logic region.

9. An integrated circuit device comprising:
a substrate comprising a base substrate layer and an insulating substrate layer;
a plurality of fin-type active regions protruding from a frontside surface of the substrate in a vertical direction and extending long in a first horizontal direction to define a trench region on the substrate;
a plurality of source/drain regions on the plurality of fin-type active regions;
a device isolation layer on a sidewall of each of the plurality of fin-type active regions in the trench region;
a via power rail between the plurality of fin-type active regions, between the plurality of source/drain regions and penetrating the device isolation layer in the vertical direction; and
a backside power rail penetrating the substrate in the vertical direction from a backside surface of the substrate to contact an end of the via power rail,
wherein a lower surface of the trench region and an upper surface of the insulating substrate layer are provided at a same vertical level.

10. The integrated circuit device of claim 9, wherein the insulating substrate layer comprises silicon oxide (SiOx), silicon nitride (SIN), or a combination thereof, and
wherein the base substrate layer comprises a semiconductor material.

11. The integrated circuit device of claim 9, wherein a lower surface of each of the plurality of fin-type active regions, a lower surface of the device isolation layer and the upper surface of the insulating substrate layer are provided at a same vertical level.

12. The integrated circuit device of claim 9, wherein the backside power rail penetrates the insulating substrate layer in the vertical direction.

13. The integrated circuit device of claim 9, wherein a thickness of the insulating substrate layer in the vertical direction is about 10 nm to about 20 nm.

14. The integrated circuit device of claim 9, further comprising:
a plurality of source/drain contacts spaced apart from the via power rail and respectively connected to the plurality of source/drain regions;
a plurality of source/drain via contacts spaced apart from the via power rail and respectively connected to the plurality of source/drain contacts; and
a plurality of upper wiring layers respectively provided on the plurality of source/drain via contacts,
wherein the via power rail is connected to the plurality of source/drain via contacts via at least one upper wiring layer selected from the plurality of upper wiring layers.

15. The integrated circuit device of claim 9, wherein the substrate comprises a memory region and a logic region, and
wherein a lower surface of the trench region is constant in each of the memory region and the logic region.

16. The integrated circuit device of claim 9, further comprising:
at least one nanosheet provided on the plurality of fin-type active regions; and
a gate line surrounding the at least one nanosheet and extending long in a second horizontal direction crossing the first horizontal direction.

17. The integrated circuit device of claim 9, wherein an upper surface of the backside power rail and the upper surface of the insulating substrate layer are provided at the same vertical level.

18. The integrated circuit device of claim 9, wherein a lower surface of the via power rail and the upper surface of the insulating substrate layer are provided at the same vertical level.

19. An integrated circuit device comprising:
a substrate comprising a base substrate layer comprising a semiconductor material and an insulating substrate layer, the insulating substrate layer comprising silicon oxide (SiOx), silicon nitride (SIN), or a combination thereof;
a plurality of cell regions spaced apart from each other on the substrate in a first horizontal direction and each comprising a plurality of cells;
an inter-cell separation region on the substrate between the plurality of cell regions, and extending long in a second horizontal direction crossing the first horizontal direction;
a plurality of power lines on a backside surface of the substrate, the plurality of power lines crossing the plurality of cell regions and the inter-cell separation region, and extending in parallel in the first horizontal direction;
a plurality of via power rails in the inter-cell separation region; and
a backside power rail penetrating the substrate in a vertical direction from the backside surface of the substrate to contact an end of each of the plurality of via power rails,
wherein each of the plurality of cells comprises:
a fin-type active region protruding from a frontside surface of the substrate in the vertical direction and extending long in the first horizontal direction to define a trench region on the substrate;
a device isolation layer on sidewalls of the fin-type active region in the trench region;
at least one nanosheet provided on the fin-type active region; and
a gate line surrounding the at least one nanosheet and extending long in the second horizontal direction, and
wherein a lower surface of the trench region and a vertical level of an upper surface of the insulating substrate layer are provided at a same vertical level.

20. The integrated circuit device of claim 19, wherein a lower surface of each of a plurality of trench regions in the plurality of cell regions, a lower surface of each of a plurality of trench regions in the inter-cell separation region, and the upper surface of the insulating substrate layer are provided at the same vertical level.
